(19) United States
(12) Patent Application Publication
(10) Pub. No.: US 2003/0022498 A1
(43) Pub. Date: Jan. 30, 2003

(54) CMP system and method for efficiently processing semiconductor wafers

(76) Inventor: In Kwon Jeong, Sunnyvale, CA (US)

Correspondence Address: Wilson & Ham, PMB: 348 2530 Berryessa Road, San Jose, CA, 95132, US

(21) Appl. No.: 09/917,344

(22) Filed: Jul. 27, 2001

(51) Int. Cl. H01L 21/302; H01L 21/461; C23F 1/00

(52) U.S. Cl. 438/691; 438/689; 438/745; 156/345.12

(57) ABSTRACT

A chemical mechanical polishing (CMP) system and method for efficiently processing semiconductor wafers utilizes wafer transfer mechanisms that are strategically positioned in the system to efficiently transfer the wafers through the system. The efficient transfer of semiconductor wafers within the CMP system reduces congestion of wafers at various units of the system, which increases the throughput of the system. In addition to the efficient transfer of semiconductor wafers, the strategic positioning of the wafer transfer mechanisms minimizes the footprint of the CMP system.

### FIELD OF THE INVENTION

The invention relates generally to semiconductor wafer processing, and more particularly to a chemical mechanical polishing (CMP) system.

### BACKGROUND OF THE INVENTION

During a fabrication process of a high density multi-layered semiconductor device, one of the most important processing steps is planarizing a layer of a semiconductor wafer by removing uneven topographic features of the wafer. The layer planarization allows patterns that are subsequently formed above that layer to be more uniform. In the case of conductive patterns, the planarization of the underlying layer reduces the probability of electrical shorts between the conductive patterns, which is a growing concern as the density of microelectronic circuitry included in a semiconductor device is progressively increased.

Chemical mechanical polishing (CMP) is a well-accepted technique to planarize a layer of a semiconductor wafer during the fabrication process by chemically and mechanically removing uneven topographic features of the wafer. A conventional CMP technique involves polishing the surface of a wafer with a rotating polishing pad using a slurry of colloidal particles in an aqueous solution. The slurry promotes planarization of the wafer surface by producing a chemical reaction with the wafer surface and by providing abrasives to “grind” the wafer surface with the polishing pad.

Conventional CMP polishers may include one or more polishing pads to simultaneously polish multiple semiconductor wafers. Some conventional CMP polishers are designed to polish one semiconductor wafer on a single polishing pad. Other conventional CMP polishers are designed to simultaneously polish a number of semiconductor wafers on a single polishing pad. Many conventional CMP polishers operate with post-CMP cleaners that clean and dry the polished semiconductor wafers.

CMP systems have been developed that integrate CMP polishers with post-CMP cleaners. A conventional CMP system may include one or more CMP polishers to polish multiple semiconductor wafers in series or in parallel. In addition, a conventional CMP system may include one or more post-CMP cleaners to clean and dry the polished semiconductor wafers. These conventional CMP systems include wafer transfer mechanisms to transfer semiconductor wafers from the CMP polisher(s) to the post-CMP cleaner(s). The wafer transfer mechanisms also transfer the semiconductor wafers between a wafer cassette and the CMP polisher(s) and/or between the post-CMP cleaner(s) and the wafer cassette. For CMP systems with multiple CMP polishers, the wafer transfer mechanisms also transfer the semiconductor wafers from one CMP polisher to the next CMP polisher.

A concern with these conventional integrated CMP systems is that the wafer transfer mechanisms tend to increase the footprint and/or decrease the throughput of the systems, which are two of the most important criteria for an integrated CMP system.

In view of the above concern, there is a need for a CMP system and method for processing semiconductor wafers that provides increased throughput and reduced footprint for the system.

### SUMMARY OF THE INVENTION

A chemical mechanical polishing (CMP) system and method for efficiently processing semiconductor wafers utilizes wafer transfer mechanisms that are strategically positioned in the system to efficiently transfer the wafers through the system. The efficient transfer of semiconductor wafers within the CMP system reduces congestion of wafers at various units of the system, which increases the throughput of the system. In addition to the efficient transfer of semiconductor wafers, the strategic positioning of the wafer transfer mechanisms minimizes the footprint of the CMP system.

A CMP system in accordance with the invention includes a supply unit that is configured to accommodate a plurality of objects, a polishing unit that is configured to polish the objects, a post-polishing unit that is configured to process the objects after being polished by the polishing unit, an intermediate object transfer mechanism that is configured to transfer the objects between the polishing unit and the post-polishing unit, and a supply mechanism that is configured to transfer the objects from the supply unit to the intermediate object transfer mechanism such that the objects can be relayed to the polishing unit.

In an embodiment, the intermediate object transfer mechanism includes a first object transfer device and a second object transfer device that are configured to selectively transfer objects to and from the polishing unit. In this embodiment, one of the first and second object transfer devices may be configured to directly transfer some of the objects from the polishing unit to the post-polishing unit.

In an embodiment, the post-polishing unit includes a first object cleaner that is configured to clean some of the objects that have been polished by the polishing unit. The first object cleaner may include a thickness measurement unit to measure the thickness of features on the surfaces of the objects.

In an embodiment, the post-polishing may also include a secondary polisher to further polish some of the objects that have been polished by the polishing unit. In this embodiment, the secondary polisher is positioned on one side of the supply mechanism between the polishing unit and the supply unit, while the first object cleaner is positioned on an opposite side of the supply mechanism between the polishing unit and the supply unit.

In an embodiment, the post-polishing unit may also include a second object cleaner that is configured to clean some of the objects that have been polished by the polishing unit. In this embodiment, the first object cleaner is positioned on one side of the supply mechanism between the polishing unit and the supply unit, while the second object cleaner is positioned on an opposite side of the supply mechanism. In addition to the second object cleaner, the post-polishing unit may include first and second secondary polishers to further polish some of the objects that have been polished by the polishing unit. The first secondary polisher is positioned on the same side of the supply mechanism as the first object cleaner. The second secondary polisher is positioned on the same side of the supply mechanism as the second object cleaner.

In one embodiment, the supply unit includes an object load assembly that is configured to vertically position a plurality of object storage housings. The object load assembly may be configured to vertically move the plurality of object storage housings. The supply unit may also include object unload assemblies that are each configured to vertically position a plurality of object storage housings. In this embodiment, at least one of the object unload assemblies may be configured to vertically move the plurality of object storage housings that are positioned by that object unload assembly.

In another embodiment, the supply unit includes an object load assembly and an object unload assembly, which are each configured to vertically position a plurality of object storage housings. In this embodiment, one of the object load and unload assemblies may be configured to vertically move the plurality of object storage housings.

In an embodiment, the supply unit includes an object storage housing that is configured to be mobile to travel from the supply unit to the supply mechanism.

In an embodiment, the system further includes a first object transfer station to receive the objects that are to be transferred to the polishing unit by the intermediate object transfer mechanism. The first object transfer station may include a thickness measurement unit to measure the thickness of features on the surfaces of the objects. In this embodiment, the system may also include a second object transfer station to receive the objects that have been polished by the polishing unit. The second object transfer station is vertically positioned with respect to the first object transfer station.

A method in accordance with the invention includes the steps of transferring objects from a supply unit of a polishing system to an interface region of the polishing system through an object transfer region of the polishing system, which is located between the supply unit and the interface region, transferring the objects from the interface region to a polishing unit of the polishing system, and transferring the objects from the polishing unit to a post-polishing unit of the polishing system.

In an embodiment, the step of transferring the objects from the interface region to the polishing unit includes selectively transferring the objects to the polishing unit using first and second object transfer mechanisms such that some of the objects are transferred by the first object transfer mechanism and some of the objects are transferred by the second object transfer mechanisms.

In an embodiment, the method further includes the step of measuring the thickness of features on surfaces of the objects at a measurement station of an object cleaner of the post-polishing unit.

In one embodiment, the step of transferring the objects from the polishing unit to the post-polishing unit includes transferring some of the objects to an object cleaner of the post-polishing unit to clean the objects and transferring some of the objects to a secondary polisher of the post-polishing unit to further polish the objects. The object cleaner is positioned on one side of the object transfer region between the polishing unit and the supply unit, while the secondary polisher is positioned on an opposite side of the object transfer region between the polishing unit and the supply unit.

In another embodiment, the step of transferring the objects from the polishing unit to the post-polishing unit includes transferring some of the objects to a first object cleaner of the post-polishing unit to clean the objects and transferring some of the objects to a second object cleaner of the post-polishing unit. The first object cleaner is positioned on one side of the object transfer region between the polishing unit and the supply unit, while the second object cleaner is positioned on an opposite side of the object transfer region between the polishing unit and the supply unit. In this embodiment, the step of transferring the objects from the polishing unit to the post-polishing unit may further include selectively transferring some of the objects to first and second secondary polishers of the post-polishing unit to further polish the objects. The first secondary polisher is positioned on the same side of the object transfer region as the first object cleaner. The second secondary polisher is positioned on the same side of the object transfer region as the second object cleaner.

In an embodiment, the method further includes the step of vertically moving a plurality of object storage housings within the supply unit of the polishing system.

In an embodiment, the step of transferring the objects from the supply unit of the polishing system to the interface region of the polishing system through the object transfer region of the polishing system includes serially relaying the objects to first and second object transfer mechanisms to transfer the objects from the supply unit to the interface region. The first and second object transfer mechanisms are positioned in the object transfer region of the polishing system. In this embodiment, the method may further include the step of transferring some of the objects from the post-polishing unit to the supply unit using the first object transfer mechanism.

In an embodiment, the method further includes the step of laterally moving an object storage housing from the supply unit across a portion of the object transfer region of the polishing system to position the object storage housing close to the interface region of the polishing system.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a plan view of a chemical mechanical polishing (CMP) system in accordance with a first embodiment of the present invention.

FIG. 2 is a partial perspective view of the CMP system of FIG. 1 from the viewpoint of the polishing unit of the system.

FIG. 3A is a plan view of a cleaning unit that may be included in the CMP system of FIG. 1.

FIG. 3B is a plan view of a cleaning unit with a back-end measurement station that may be included in the CMP system of FIG. 1.

FIG. 3C is a plan view of a cleaning unit with a front-end measurement station that may be included in the CMP system of FIG. 1.

FIG. 4 is a plan view of a chemical mechanical polishing (CMP) system in accordance with a second embodiment of the present invention.

FIG. 5 is a partial perspective view of the CMP system of FIG. 4 from the viewpoint of the polishing unit of the system.

FIG. 6 is a plan view of a chemical mechanical polishing (CMP) system in accordance with a third embodiment of the present invention.

FIG. 7 is a partial perspective view of the CMP system of FIG. 6 from the viewpoint of the polishing unit of the system.

FIG. 8 is a plan view of a chemical mechanical polishing (CMP) system in accordance with a fourth embodiment of the present invention.

FIG. 9 is a partial perspective view of the CMP system of FIG. 8 from the viewpoint of the polishing unit of the system.

FIG. 10 is a plan view of a chemical mechanical polishing (CMP) system in accordance with a fifth embodiment of the present invention.

FIG. 11 is a partial perspective view of the CMP system of FIG. 10 from the viewpoint of the polishing unit of the system.

FIG. 12 is a side view of a modified wafer supply unit suitable for the CMP systems of FIGS. 1 and 6.

FIG. 13 is a side view of a modified wafer supply unit suitable for the CMP systems of FIGS. 4, 8 and 10.

FIG. 14 is a plan view of a first alternative wafer transfer unit suitable for the CMP system of FIG. 1.

FIG. 15 is a plan view of a first alternative wafer transfer unit suitable for the CMP systems of FIGS. 4, 8 and 10.

FIG. 16 is a plan view of a second alternative wafer transfer unit suitable for the CMP systems of FIGS. 1 and 6.

FIG. 17 is a plan view of a second alternative wafer transfer unit suitable for the CMP systems of FIGS. 4, 8 and 10.

FIG. 18 is a process flow diagram of a method of processing semiconductor wafers in accordance with the present invention.

### DETAILED DESCRIPTION OF THE INVENTION

A chemical mechanical polishing (CMP) system and method for efficiently processing semiconductor wafers utilizes wafer transfer mechanisms that are strategically positioned in the system to efficiently transfer the wafers through the system. The efficient transfer of semiconductor wafers within the CMP system reduces congestion of wafers at various units of the system, which increases the throughput of the system. In addition to the efficient transfer of semiconductor wafers, the strategic positioning of the wafer transfer mechanisms minimizes the footprint of the CMP system.

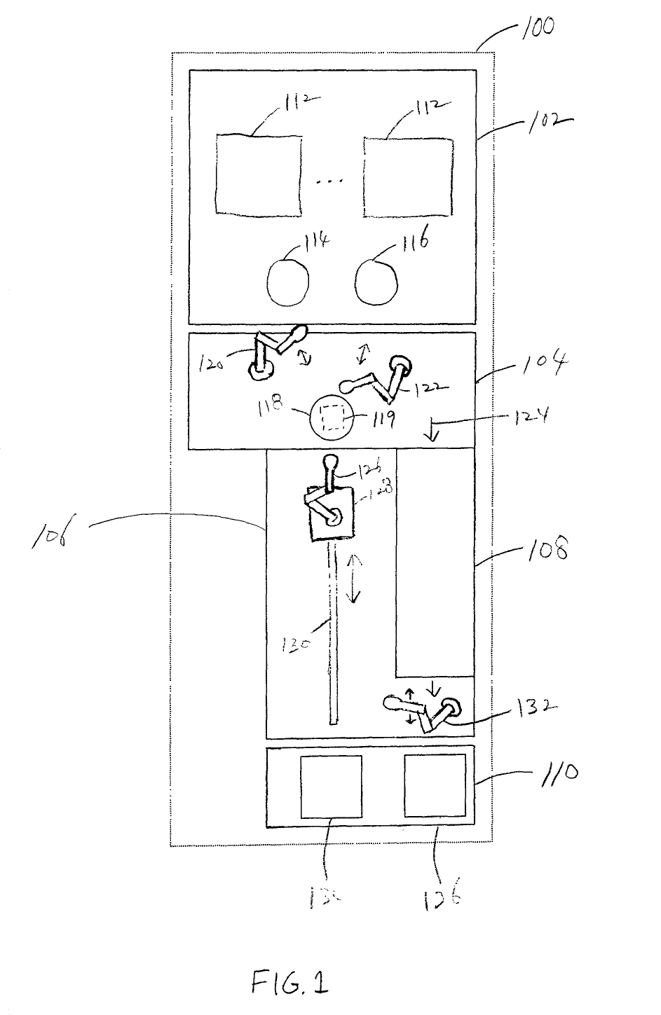

With reference to FIG. 1, a CMP system 100 in accordance with a first embodiment of the present invention is shown. The CMP system includes a polishing unit 102, an interface unit 104, a wafer transfer unit 106, a wafer cleaning unit 108, and a wafer supply unit 110. The polishing unit 102 operates to polish semiconductor wafers that are supplied from the wafer supply unit 110. The wafer cleaning unit 108 operates to clean or clean-and-dry the polished semiconductor wafers. The semiconductor wafers are transferred between the wafer supply unit 110, the polishing unit 102, and the wafer cleaning unit 108 by the interface unit 104 and the wafer transfer unit 106. The interface unit and the wafer transfer unit include wafer transfer mechanisms that are strategically positioned to efficiently transfer the semiconductor wafers, while minimizing the footprint of the CMP system 100.

The polishing unit 102 of the CMP system 100 includes one or more CMP polishers 112. If the polishing unit includes multiple CMP polishers, the polishing unit may be configured to sequentially polish semiconductor wafers using two or more CMP polishers. As an example, if the polishing unit includes multiple CMP polishers, the polishing unit may be configured to polish a given semiconductor wafer on a first CMP polisher and then to subsequently polish the wafer on one or more CMP polishers. Alternatively, the polishing unit may be configured to polish multiple semiconductor wafers in parallel. The types of CMP polishers that may be included in the polishing unit are CMP polishers that utilize a single polishing pad with a single wafer carrier, CMP polishers that utilize a single polishing pad with multiple wafer carriers and/or CMP polishers with multiple polishing pads with one or more wafer carriers.

As shown in FIG. 1, the polishing unit 102 includes a wafer load station 114 and a wafer unload station 116. The wafer load station 114 is configured to receive semiconductor wafers from the interface unit 104 that are to be polished by the polishing unit. The wafer unload station 116 is configured to receive semiconductor wafers that have been polished by the polishing unit and are ready to be transferred to the wafer cleaning unit 108. In another embodiment, the polishing unit may include a single wafer load/unload station (not shown), which functions as a common station to receive semiconductor wafers to be polished and the polished semiconductor wafers. In still another embodiment, the polishing unit may not include any wafer stations. In this embodiment, the semiconductor wafers to be polished are directly loaded onto the wafer carriers (not shown) of the CMP polishers 112 included in the polishing unit by the interface unit, and the polished semiconductor wafers are directly unloaded from the wafer carriers by the interface unit.

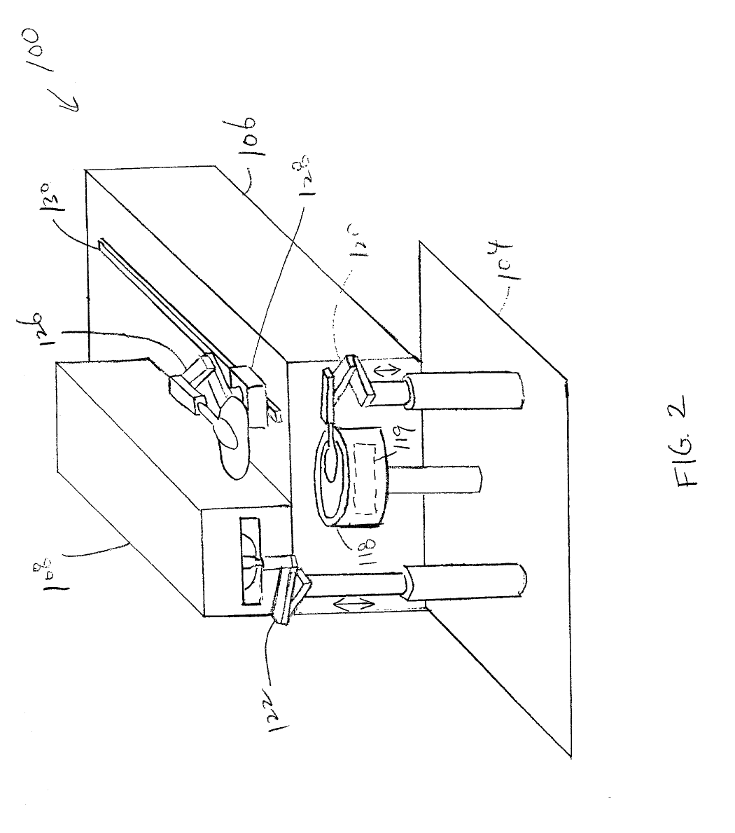

The interface unit 104 of the CMP system 100 operates to transfer semiconductor wafers to and from the polishing unit 102. The interface unit is situated adjacent to the polishing unit between the polishing unit and the wafer transfer unit 106, as shown in FIG. 1. The interface unit includes a wafer relay station 118 and wafer transfer robots 120 and 122. The wafer relay station is configured to receive semiconductor wafers from the wafer transfer unit 106 that are to be polished by the polishing unit 102, as illustrated in FIG. 2. FIG. 2 is a partial perspective view of the CMP system 100 without the wafer supply unit 110 from the viewpoint of the polishing unit. The wafer relay station may include an optional thickness measurement unit 119 to optically measure the thickness of features on semiconductor wafers before and/or after the wafers are polished at the polishing unit 102. The optional thickness measurement unit may be any known type of thickness measurement devices that are commonly used to measure such thickness of semiconductor wafer features during wafer processing. The optional thickness measurement unit may be positioned to measure the features on either the upper surface or the lower surface of a semiconductor wafer placed on the wafer relay station 119. Thus, the semiconductor wafers are placed on the wafer relay station with the surface to be polished either facing upward or downward, depending on the position of the optional thickness measurement unit. Wafer thickness measurement devices are well known in the field of wafer processing, and thus the optional wafer thickness measurement unit 119 is not described in detail herein.

The wafer transfer robots 120 and 122 of the interface unit 104 are designed to move semiconductor wafers in both horizontal and vertical directions, as illustrated in FIGS. 1 and 2. Thus, the wafer transfer robots 120 and 122 can raise and lower semiconductor wafers, as well as laterally transfer the wafers between the wafer transfer relay station 118 and the polishing unit 102. The wafer transfer robot 120 can be configured to exclusively transfer semiconductor wafers from the wafer relay station 118 to the wafer load station 114, the wafer load/unload station or the wafer carriers of the polishing unit 102. Similarly, the wafer transfer robot 122 can be configured to exclusively transfer polished semiconductor wafers from the wafer unload station 116, the wafer load/unload station or the wafer carriers of the polishing unit to the wafer cleaning unit 108, as indicated by the arrow 124 in FIG. 1. Thus, the wafer transfer robots of the interface unit 104 can efficiently transfer semiconductor wafers to and from the polishing unit 102. The wafer transfer robot 122 may also be configured to turn over semiconductor wafers, since polished semiconductor wafers may need to be turned over to be processed by the wafer cleaning unit 108. Similarly, the wafer transfer robot 120 may also be configured to turn over semiconductor wafers, depending on the orientation of the wafers when received at the wafer relay station 118 of the interface unit 104 and the type of CMP polishers 112 included in the polishing unit 102.

The wafer transfer unit 106 of the CMP system 100 operates to transfer semiconductor wafers from the wafer supply unit 110 to the interface unit 104. The wafer transfer unit is situated between the wafer supply unit and the interface unit. The wafer transfer unit includes a wafer transfer robot 126 mounted on a platform 128, which is on a track 130. The track extends from the wafer supply unit to the interface unit. Consequently, the track allows the wafer transfer robot 126 to move between the interface unit and the wafer supply unit. Thus, the wafer transfer robot 126 is able to transfer semiconductor wafers from the wafer supply unit to the wafer relay station 118 of the interface unit. Similar to the wafer transfer robots 120 and 122 of the interface unit, the wafer transfer robot 126 may be configured to turn over semiconductor wafers. The semiconductor wafers may need to be turned over before reaching the polishing unit 102. Thus, in this situation, one of the wafer transfer robots 120 and 126 needs to turn over the semiconductor wafers. Consequently, if the wafer transfer robot 126 is configured turn over the semiconductor wafers, the wafer transfer robot 120 may not be configured to turn over the wafers. However, if the wafer transfer robot 126 is not configured turn over the semiconductor wafers, the wafer transfer robot 120 may be configured to turn over the wafers.

The wafer transfer unit 106 also includes a wafer transfer robot 132, which is situated between the wafer cleaning unit 108 and the wafer supply unit 110. The wafer transfer robot 132 is configured to transfer semiconductor wafers that have been processed by the wafer cleaning unit to the wafer supply unit. The wafer transfer robot may also be configured to turn over the semiconductor wafers when transferring the wafers to the wafer supply unit.

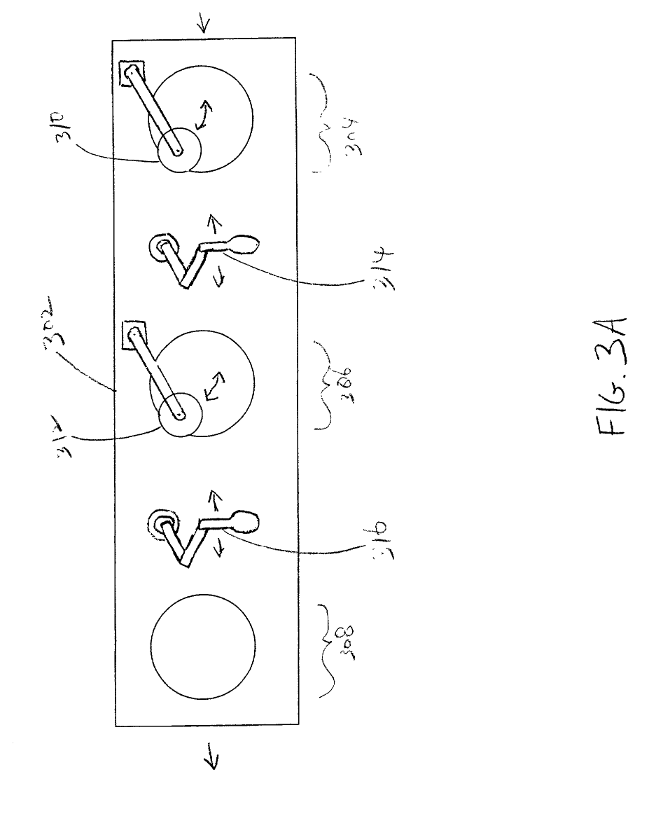

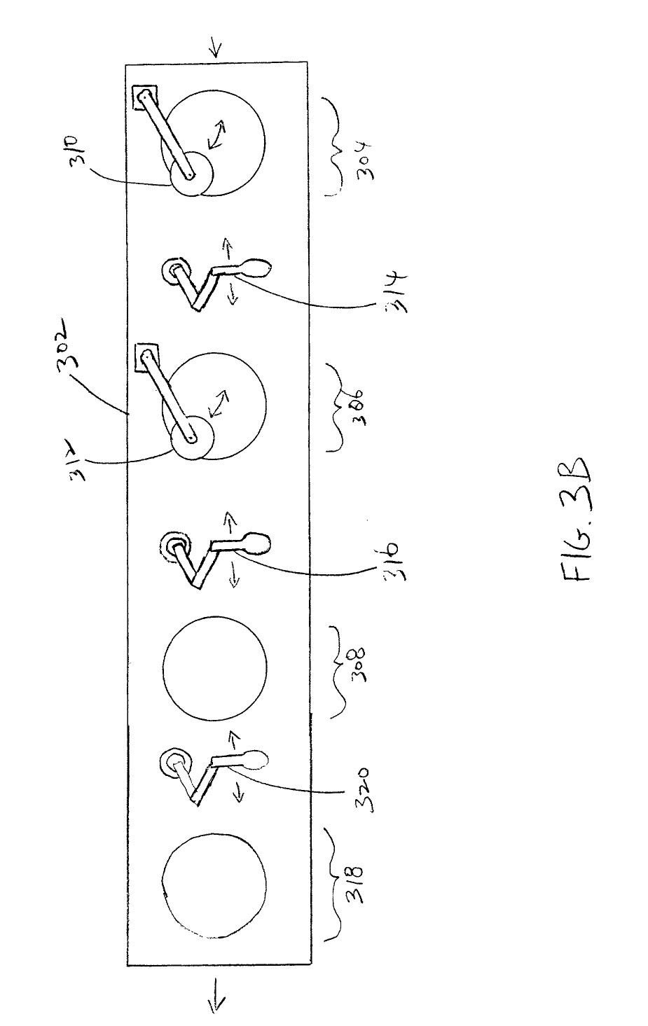

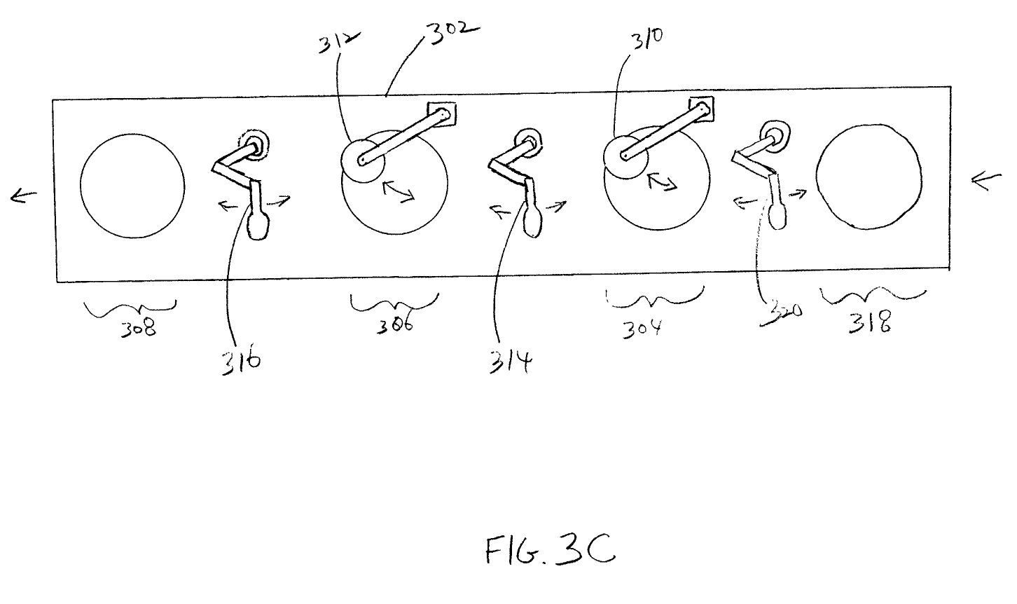

The wafer cleaning unit 108 of the CMP system 100 operates to clean or to clean-and-dry semiconductor wafers that have been polished by the polishing unit 102. The wafer cleaning unit is situated between the interface unit 104 and the wafer supply unit 110, next to the wafer transfer unit 106. The cleaning unit may be any type of wafer cleaners that can clean or clean-and-dry polished semiconductor wafers. In FIG. 3A, an exemplary wafer cleaning unit 302 that can be included in the CMP system 100 is shown. The wafer cleaning unit 302 includes three cleaning stations 304, 306 and 308. The first cleaning station 304 uses a cleaning brush 310 with a chemical solution, such as NH₄OH-added deionized water, to remove remaining slurry particles on polished semiconductor wafers. Similarly, the second cleaning station 306 uses a cleaning brush 312 with the same or different solution, such as diluted HF solution, to etch the surfaces of the polished semiconductor wafers that have been contaminated with slurry. The third cleaning station 308 uses deionized water to rinse the semiconductor wafers. In addition, the third cleaning station spins the semiconductor wafers to dry the wafers. The wafer cleaning unit 302 also includes wafer transfer robots 314 and 316 to transfer the semiconductor wafers from the first cleaning station to the second cleaning station and then to the third cleaning station. A given semiconductor wafer is transferred to the first cleaning station 304 by the wafer transfer robot 122 of the interface unit 104, as illustrated in FIG. 2. When the semiconductor wafer is processed by the third cleaning unit 308, the wafer is removed from the third cleaning unit by the wafer transfer robot 132 of the wafer transfer unit 106, and transferred to the wafer supply unit 110. The wafer cleaning unit 108 of the CMP system 100 may include one to four cleaning stations, depending on the type of the wafer cleaning unit.

The exemplary wafer cleaning unit 302 may further includes an optional measurement station 318 with a supplemental wafer transfer robot 320, as shown in FIGS. 3B and 3C. The measurement station may be positioned at the end of the wafer cleaning unit 302, next to the third cleaning station 308, as illustrated in FIG. 3B. Alternatively, the measurement station may be positioned at the front of the wafer cleaning unit, next to the first cleaning station 304, as illustrated in FIG. 3C. If the measurement station is positioned at the end of the wafer cleaning unit, the wafer transfer robot 320 is positioned between the third cleaning station and the measurement station to transfer semiconductor wafers from the third cleaning station to the measurement station. In contrast, if the measurement station is positioned at the front of the wafer cleaning unit, the wafer transfer robot 320 is positioned between the measurement station and the first cleaning station to transfer semiconductor wafers from the measurement station to the first cleaning station. In the latter configuration, the semiconductor wafers are initially transferred to the measurement station by the wafer transfer robot 122 of the interface unit 104.

The measurement station 318 is configured to measure the thickness of features on the polished surface of the semiconductor wafers and/or to detect defects on the polished surface of the wafers using any known technology. The thickness measurement information derived from the measurement station may be used in conjunction with the information derived from the thickness measurement unit 119 of the wafer relay station 118 to determine whether the polishing unit 102 is polishing semiconductor wafers within defined operational parameters.

The wafer supply unit 110 of the CMP system 100 operates to supply semiconductor wafers that are to be processed by the system and to receive the finished semiconductor wafers. The wafer supply unit is configured to hold a wafer load cassettes 134 and a wafer unload cassette 136. The wafer load cassette 134 is used to supply the semiconductor wafers that are to be processed by the system, while the wafer unload cassette 136 is used to receive the finished semiconductor wafers.

The operation the CMP system 100 of FIG. 1 is now described. Initially, the wafer load cassette 134 with a supply of semiconductor wafers to be processed is inserted into the wafer supply unit 110. The wafer transfer robot 126 of the wafer transfer unit 106 selects a first semiconductor wafer from the wafer load cassette 134 and transfers that selected wafer to the wafer relay station 118 of the interface unit 104 by moving along the track 130 from the wafer supply unit to the interface unit. At the wafer relay station, the thickness of features on the first semiconductor wafer may be measured by the optional thickness measurement unit 119. The semiconductor wafer is then picked up from the wafer relay station by the wafer transfer robot 120 of the interface unit 104 and transferred to the wafer load station 114, the wafer load/unload station or one of the wafer carriers of the polishing unit 102. During this transfer from the wafer load cassette 134 of the wafer supply unit 110 to the polishing unit 102, the semiconductor wafer may be turned over by either the wafer transfer robot 126 of the wafer transfer unit or the wafer transfer robot 120 of the interface unit.

The semiconductor wafer is then polished by one or more CMP polishers 112 of the polishing unit 102. The polished semiconductor wafer is picked up from the wafer unload station, the wafer load/unload station or the wafer carrier of the polishing unit by the wafer transfer robot 122 of the interface unit 104 and transferred to the wafer cleaning unit 108, where the wafer is cleaned, dried and/or measured for feature thickness. During this transfer to the cleaning unit, the polished semiconductor wafer may be turned over by the wafer transfer robot 122. After the semiconductor wafer has been processed by the wafer cleaning unit, the wafer transfer robot 132 of the wafer transfer unit 106 transfers the wafer to the wafer unload cassette 136 of the wafer supply unit 110.

Shortly after the first semiconductor wafer has been transferred from the wafer load cassette 134 of the wafer supply unit 110 to the wafer relay station 118 of the interface unit 104 by the wafer transfer robot 126 of the wafer transfer unit 106, the wafer transfer robot 126 returns to the wafer supply unit to select and transfer a second semiconductor wafer from the wafer load cassette to the wafer relay station. The second semiconductor wafer is processed in the same manner as the first semiconductor wafer. In this fashion, all the semiconductor wafers from the wafer load cassette 134 are continually processed by the CMP system and placed in the wafer unload cassette 136.

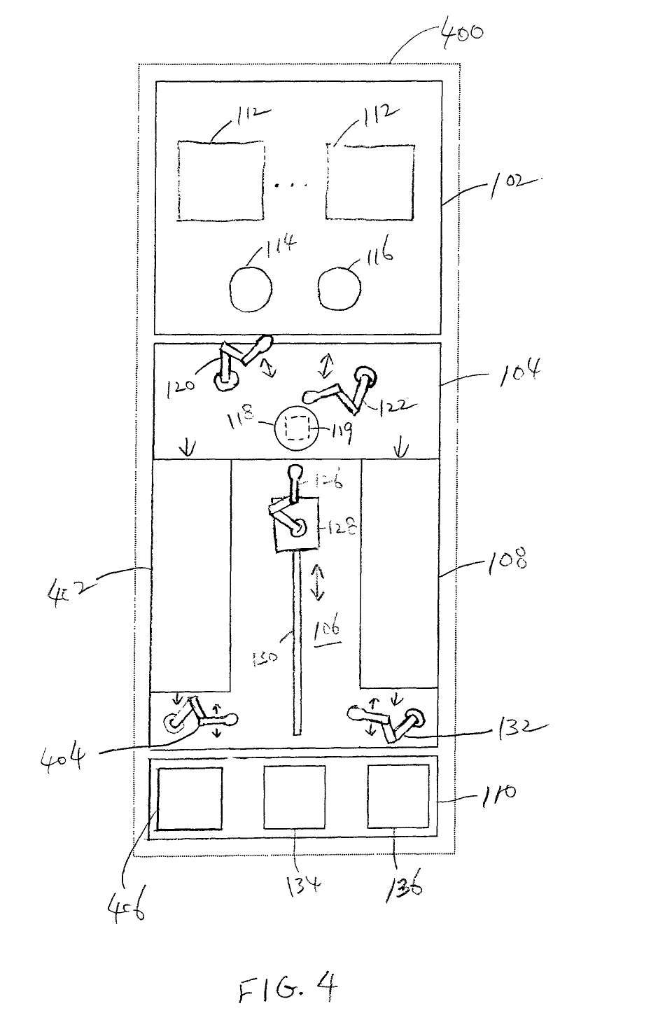

Turning now to FIG. 4, a CMP system 400 in accordance with a second embodiment of the invention is shown. Similar to the CMP system of FIG. 1, the CMP system of FIG. 4 includes the polishing unit 102, the interface unit 104, the wafer transfer unit 106, the wafer cleaning unit 108 and the wafer supply unit 110. However, the CMP system 400 of FIG. 4 includes an additional wafer cleaning unit 404, which may be identical to the wafer cleaning unit 108. The additional wafer cleaning unit 402 is positioned between the interface unit and the wafer supply unit on the opposite side of the wafer transfer unit, as compared to the wafer cleaning unit 108. Furthermore, in the second embodiment, the wafer transfer unit 106 includes a third wafer transfer robot 404, which is positioned between the additional wafer cleaning unit 402 and the wafer supply unit 110. In addition, the wafer supply unit 110 is configured to hold another wafer unload cassette 406. The wafer unload cassette 406 is used to receive the semiconductor wafers that have been processed by the wafer cleaning unit 402.

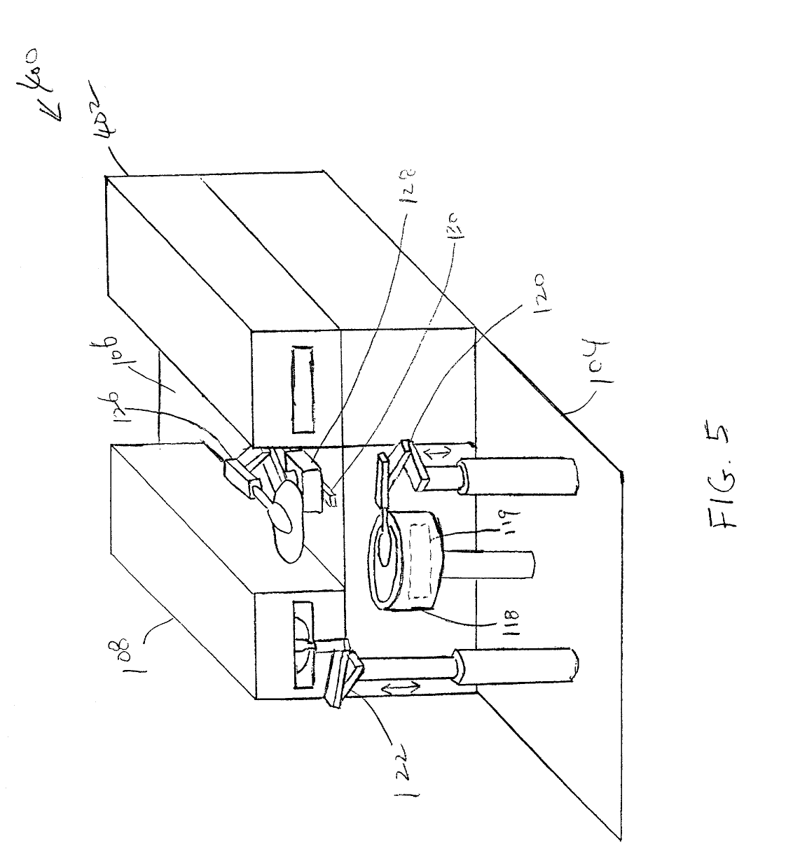

Since the CMP system 400 has two wafer cleaning unit 108 and 402, the semiconductor wafers that have been polished by the polishing unit 102 can either be processed by the wafer cleaning unit 108 or by the wafer cleaning unit 402. Preferably, the CMP system 400 is configured to process every other polished semiconductor wafers using the wafer cleaning unit 108, and the remaining polished semiconductor wafers using the wafer cleaning unit 402. The polished semiconductor wafers that are to be processed by the wafer cleaning unit 108 are transferred from the wafer unload station 116, the wafer load/unload station or a wafer carrier of the polishing unit 102 to the wafer cleaning unit 108 by the wafer transfer robot 122 of the interface unit 104, as illustrated in FIG. 5. FIG. 5 is a partial perspective view of the CMP system 400 without the wafer supply unit 110 from the viewpoint of the polishing unit. Similarly, the polished semiconductor wafers that are to be processed by the wafer cleaning unit 402 are transferred from the wafer unload station 116, the wafer load/unload station or a wafer carrier of the polishing unit 102 to the wafer cleaning unit 402 by the wafer transfer robot 120 of the interface unit 104. Since each of the wafer transfer robots 120 and 122 transfers polished semiconductor wafers from the polishing unit to one of the wafer cleaning units 108 and 402, both of the wafer transfer robots 120 and 122 may be configured to turn over the wafers. In this second embodiment, the wafer transfer robots 120 and 122 can take turns in transferring semiconductor wafers from the wafer relay station 118 of the interface unit 104 to the wafer load station 114, the wafer load/unload station or one of the wafer carriers of the polishing unit 102. Thus, the wafer transfer robots 120 and 122 can cooperatively transfer semiconductor to and from the polishing unit in an efficient manner.

The operation of the CMP system 400 of FIG. 4 is now described. Initially, the wafer load cassette 134 with a supply of semiconductor wafers to be processed is inserted into the wafer supply unit 110. The wafer transfer robot 126 of the wafer transfer unit 106 selects a first semiconductor wafer from the wafer load cassette 134 and transfers that selected wafer to the wafer relay station 118 of the interface unit 104 by moving along the track 130 from the wafer supply unit to the interface unit. At the wafer relay station, the thickness of features on the first semiconductor wafer may be measured by the optional thickness measurement unit 119. The semiconductor wafer is picked up from the wafer relay station by one of the wafer transfer robots 120 and 122 of the interface unit 104 and transferred to the wafer load station 114, the wafer load/unload station or one of the wafer carriers of the polishing unit 102. During this transfer from the wafer load cassette 134 of the wafer supply unit 110 to the polishing unit 102, the semiconductor wafer may be turned over by either the wafer transfer robot 126 of the wafer transfer unit or the wafer transfer robot of the interface unit that transferred the wafer from the wafer relay station 118 to the polishing unit 102.

The semiconductor wafer is then polished by one or more CMP polishers 112 of the polishing unit 102. The polished semiconductor wafer is picked up from the wafer unload station 116, the wafer load/unload station or the wafer carrier of the polishing unit by one of the wafer transfer robots 120 and 122 of the interface unit 104, depending on whether the wafer is to be processed by the wafer cleaning unit 108 or 402.

If the polished semiconductor wafer is to be processed by the wafer cleaning unit 108, the wafer transfer robot 122 of the interface unit 104 picks up the wafer from the wafer unload station 116, the wafer load/unload station or the wafer carrier of the polishing unit 102, and transfers the wafer to the wafer cleaning unit 108, where the wafer is cleaned, dried and/or measured for feature thickness. During this transfer, the polished semiconductor wafer may be turned over by the wafer transfer robot 122. The semiconductor wafer is then transferred from the wafer cleaning unit 108 to the wafer unload cassette 136 of the wafer supply unit 110 by the wafer transfer robot 132 of the wafer transfer unit 106.

However, if the polished semiconductor wafer is to be processed by the wafer cleaning unit 402, the wafer transfer robot 120 of the interface unit 104 picks up the wafer from the wafer unload station 116, the wafer load/unload station or the wafer carrier of the polishing unit 102, and transfers the wafer to the wafer cleaning unit 402, where the wafer is cleaned, dried and/or measured for feature thickness. During this transfer, the polished semiconductor wafer may be turned over by the wafer transfer robot 120. The semiconductor wafer is then transferred from the wafer cleaning unit 402 to the wafer unload cassette 406 of the wafer supply unit 110 by the wafer transfer robot 404 of the wafer transfer unit 106.

Shortly after the first semiconductor wafer has been transferred from the wafer load cassette 134 of the wafer supply unit 110 to the wafer relay station 118 of the interface unit 104 by the wafer transfer robot 126 of the wafer transfer unit 106, the wafer transfer robot 126 returns to the wafer supply unit to select and transfer a second semiconductor wafer from the wafer load cassette to the wafer supply station. The second semiconductor wafer is processed in the same manner as the first semiconductor wafer. However, the second semiconductor wafer is preferably cleaned, dried and/or measured for feature thickness by the wafer cleaning unit that was not used for the first semiconductor wafer. As an example, if the first semiconductor wafer was processed by the wafer cleaning unit 108, the second semiconductor wafer is processed by the wafer cleaning unit 402. Starting from the first semiconductor wafer, every other semiconductor wafers from the wafer load cassette 134 are processed in the exact same manner as the first semiconductor wafer. Similarly, starting from the second semiconductor wafer, every other semiconductor wafers from the wafer load cassette are processed in the exact same manner as the second semiconductor wafer. In this fashion, all the semiconductor wafers in the wafer load cassette are continually processed by the CMP system 400 such that half of the wafers from the wafer load cassette are cleaned, dried and/or measured for feature thickness by the wafer cleaning unit 108 and placed in the wafer unload cassette 136, and the other half of the wafers from the wafer load cassette are cleaned, dried and/or measured for feature thickness by the wafer cleaning unit 402 and placed in the wafer unload cassette 406.

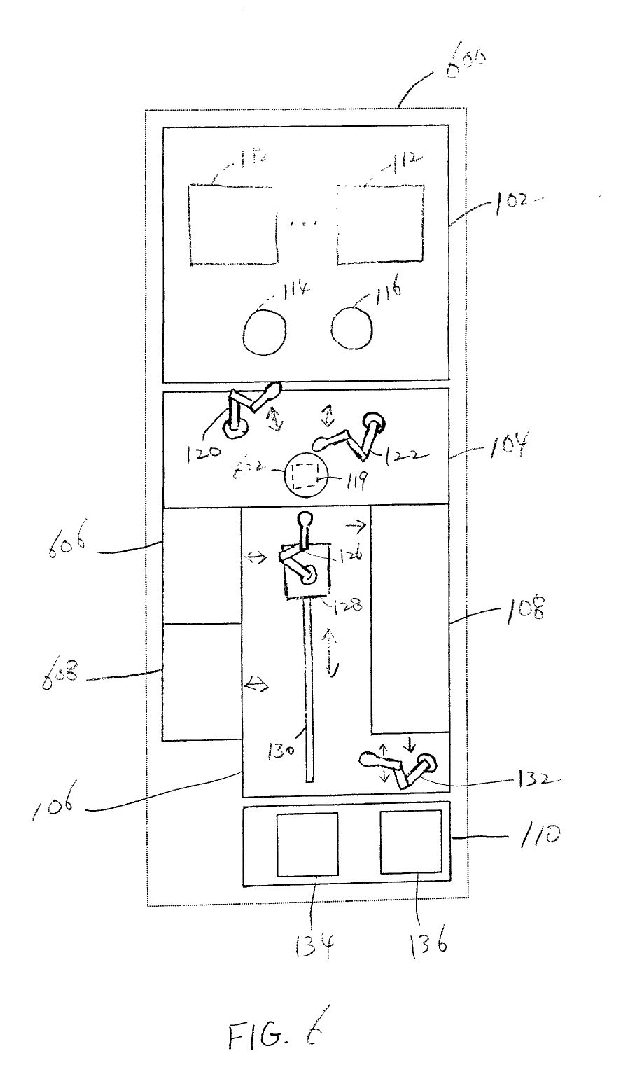

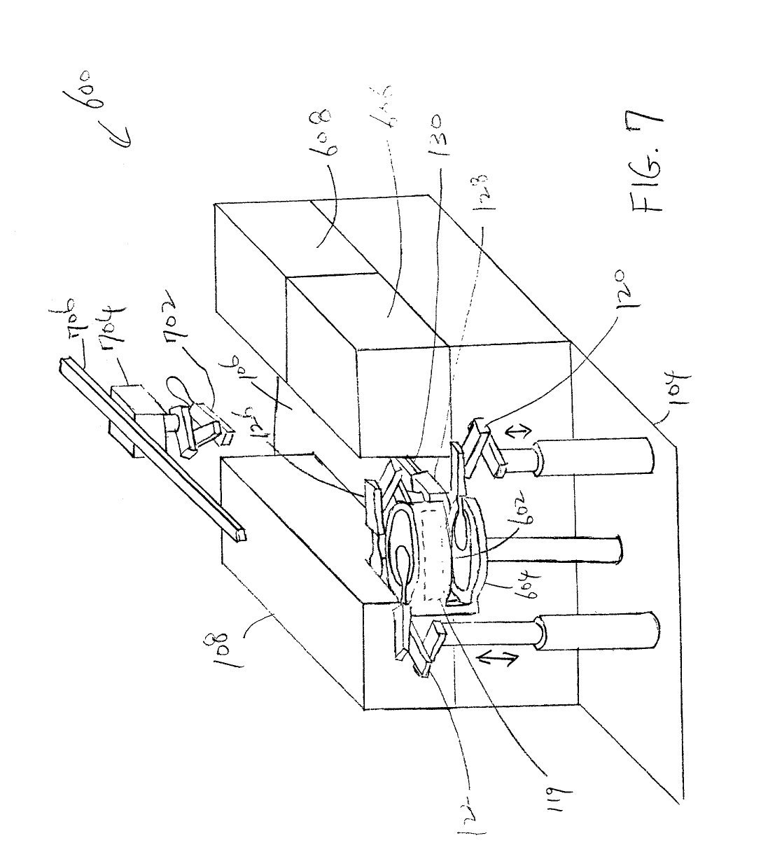

Turning now to FIG. 6, a CMP system 600 in accordance with a third embodiment of the invention is shown. The CMP system 600 of FIG. 6 includes all the components of the CMP system 100 of FIG. 1. However, in this embodiment, the wafer transfer unit 106 further includes a ceiling wafer transfer robot 702. The ceiling wafer transfer robot 702 is mounted to a platform 704, which is on an upper track 706, as illustrated in FIG. 7. FIG. 7 is a partial perspective view of the CMP system 600 without the wafer supply unit 110 from the viewpoint of the polishing unit 102. In addition, the interface unit 104 includes a wafer supply station 602 and a wafer receive station 604, which replace the wafer relay station 118 of the CMP system 100 of FIG. 1. The wafer supply station and the wafer receive station are vertically positioned such that the wafer supply station is above the wafer receive station, as illustrated in FIG. 7. The wafer supply station 602 is configured to exclusively receive semiconductor wafers from the wafer supply unit 110, while the wafer receive station 604 is configured to exclusively receive polished semiconductor wafers from the polishing unit 102. Similar to the wafer relay station 118, the wafer supply station 602 may include the optional thickness measurement unit 119 to optically measure the thickness of features on semiconductor wafers before the wafer are polished at the polishing unit 102. Although not illustrated in FIGS. 6 and 7, the wafer receive station 604 may also include the thickness measurement unit 119 to optically measure the thickness of features on the semiconductor wafers after the wafers have been polished at the polishing unit.

The CMP system 600 further includes second-step CMP polishers 606 and 608, which are positioned on the opposite side of the wafer transfer unit 104, as compared to the wafer cleaning unit 108, as illustrated in FIG. 6. Although the CMP system 600 of FIG. 6 is shown and described as having two second-step CMP polishers, the CMP system 600 may include fewer or more second-step CMP polishers. Preferably, the second-step CMP polishers are the type of CMP polishers that utilize a polishing pad that is smaller than the semiconductor wafers being polished.

In this embodiment, the wafer transfer robot 126 of the transfer unit 106 operates to transfer semiconductor wafers between the wafer receive station 604 of the interface unit 104, the second-step CMP polishers 606 and 608 and the cleaning unit 108, while the additional ceiling wafer transfer robot 702 of the transfer unit operates to transfer semiconductor wafers from the wafer load cassette 134 of the wafer supply unit 110 to the wafer supply station 602 of the interface unit. Thus, in this embodiment, the wafer transfer robot 122 of the interface unit does not transfer polished semiconductor wafers directly to the wafer cleaning unit 108. The wafer transfer robots 120 and 122 of the interface unit are configured to exclusively transfer semiconductor wafers from the wafer supply station 602 of the interface unit to the polishing unit 102, and from the polishing unit to the wafer receive station 604 of the interface unit. Each of the wafer transfer robots 120 and 122 may be designated to either transfer semiconductor wafers from the wafer supply station to the polishing unit or from the polishing unit to the wafer receive station. Alternatively, the wafer transfer robots 120 and 122 may take turns in transferring semiconductor wafers from the wafer supply station to the polishing unit and from the polishing unit to the wafer receive station.

The operation the CMP system 600 of FIG. 6 is now described. Initially, the wafer load cassette 134 with a supply of semiconductor wafers to be processed is inserted into the wafer supply unit 110. The ceiling wafer transfer robot 702 of the wafer transfer unit 106 selects a first semiconductor wafer from the wafer load cassette and transfers that selected wafer to the wafer supply station 602 of the interface unit 104 by moving along the upper track 706 from the wafer supply unit to the interface unit. At the wafer supply station, the thickness of features on the first semiconductor wafer may be measured by the optional thickness measurement unit 119. The semiconductor wafer is picked up from the wafer supply station by one of the wafer transfer robots 120 and 122 of the interface unit and transferred to the wafer unload station, the wafer load/unload station or one of the wafer carriers of the polishing unit 102. During this transfer from the wafer load cassette to the polishing unit, the semiconductor wafer may be turned over by either the ceiling wafer transfer robot 702 or the wafer transfer robot of the interface unit that transferred the wafer from the wafer supply station to the polishing unit.

The semiconductor wafer is then polished by one or more CMP polishers 112 of the polishing unit 102. The polished semiconductor wafer is picked up from the wafer unload station, the wafer load/unload station or the wafer carrier of the polishing unit by one of the wafer transfer robots 120 and 122 of the interface unit 104 and transferred to the wafer receive station 604 of the interface unit. The wafer transfer robot that transferred the polished semiconductor wafer to the wafer receive station may be the same wafer transfer robot that transferred the wafer from the wafer supply station 602 to the polishing unit. At the wafer receive station, the thickness of features on the polished semiconductor wafer may be measured by an optional thickness measurement unit (not shown). The semiconductor wafer is then picked up from the wafer receive station 604 and transferred to one of the second-step CMP polishers 606 and 608, e.g., the second-step CMP polisher 606, by the wafer transfer robot 126 of the wafer transfer unit 106. During this transfer from the polishing unit to the second-step CMP polisher 606, the semiconductor wafer may be turned over by either the wafer transfer robot of the interface unit that transferred the wafer from the polishing unit to the wafer receive station or the wafer transfer robot 126 of the wafer transfer unit. At the second-step CMP polisher 606, the semiconductor wafer is polished.

After the semiconductor wafer has been polished by the second-step CMP polisher 606, the wafer transfer robot 126 of the wafer transfer unit 106 picks up the wafer from the second-step CMP polisher 606 and transfers the wafer to the wafer cleaning unit 108, where the wafer is cleaned, dried and/or measured for feature thickness. The semiconductor wafer is then transferred from the wafer cleaning unit to the wafer unload cassette 136 of the wafer supply unit 110 by the wafer transfer robot 132 of the wafer transfer unit.

Shortly after the first semiconductor wafer has been transferred from the wafer load cassette 134 of the wafer supply unit 110 to the wafer supply station 602 of the interface unit 104 by the ceiling wafer transfer robot 702 of the wafer transfer unit 106, the wafer transfer robot 702 returns to the wafer supply unit to select and transfer a second semiconductor wafer from the wafer load cassette to the wafer supply station. The second semiconductor wafer is processed in the same manner as the first semiconductor wafer. However, the second semiconductor wafer is polished by the second-step CMP polisher that was not used for the first semiconductor wafer, e.g., the second step CMP polisher 608. In this fashion, all the semiconductor wafers from the wafer load cassette are continually processed by the CMP system 600.

As described above, semiconductor wafers are polished by either the second-step CMP polisher 606 or 608, and then cleaned, dried and/or measured for feature thickness by the wafer cleaning unit 108. However, the CMP system 600 may be configured to sequentially polish each semiconductor wafer by both the second-step CMP polishers 606 and 608 before being cleaned, dried and/or measured for feature thickness by the wafer cleaning unit 108. In this configuration, different slurries and/or different types of polishing pads may be used by each of the second-step CMP polishers.

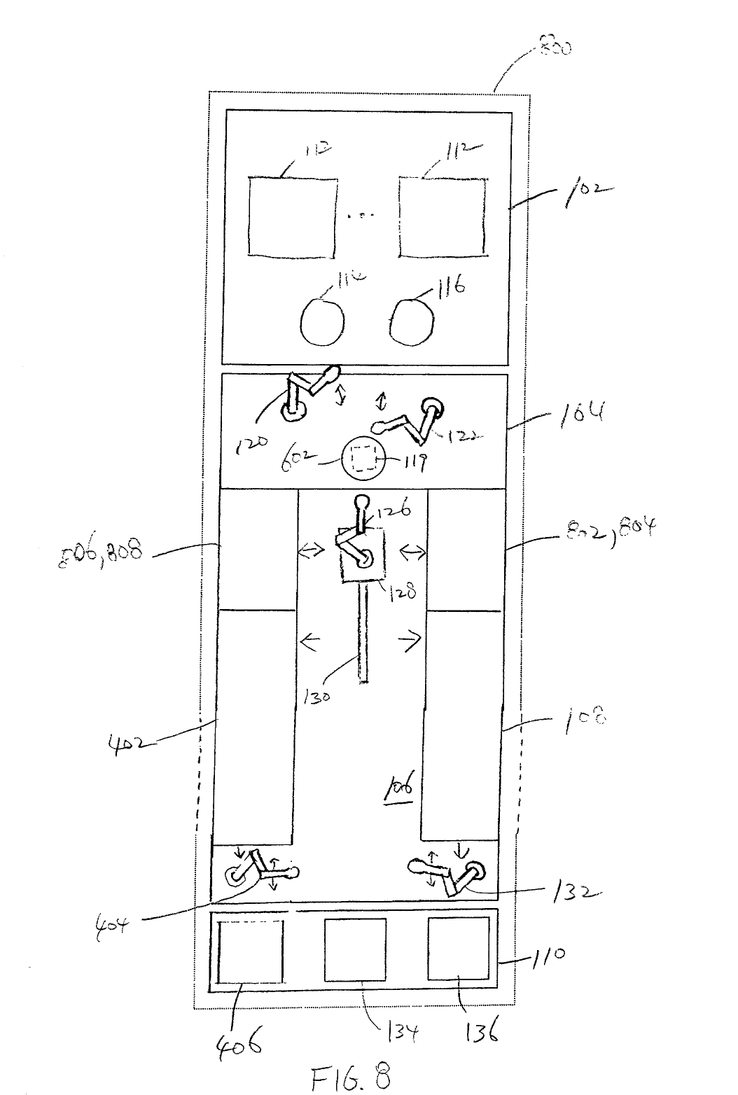

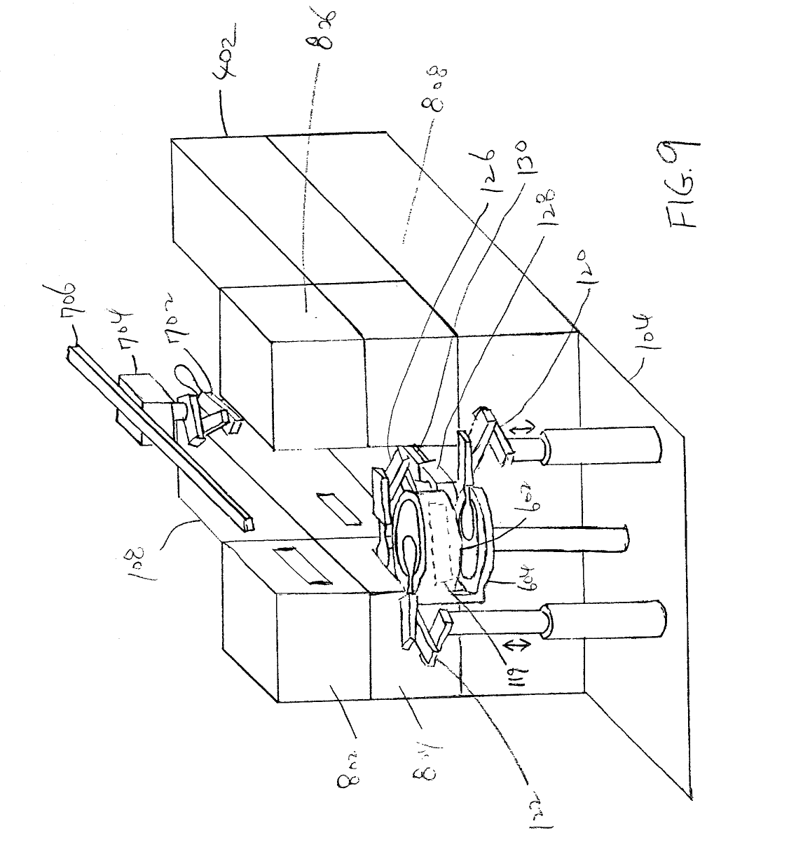

Turning now to FIG. 8, a CMP system 800 in accordance with a fourth embodiment of the invention is shown. The CMP system 800 of FIG. 8 is similar to the CMP system 600 of FIG. 6 in that the CMP system 800 includes second-step CMP polishers and that the wafer transfer unit 106 includes the ceiling wafer transfer robot 702, which is illustrated in FIG. 9. FIG. 9 is a partial perspective view of the CMP system 800 of FIG. 8 without the wafer supply unit 110 from the viewpoint of the polishing unit 102. However, in this embodiment, the CMP system 800 includes four second-step CMP polishers 802, 804, 806 and 808 and the wafer cleaning units 108 and 402. The second-step CMP polishers 802 and 804 and the wafer cleaning unit 108 are situated between the interface unit 104 and the wafer supply unit 110 on one side of the wafer transfer unit 106. The second-step CMP polishers 802 and 804 are vertically stacked, next to the interface unit 104, as shown in FIG. 9. The wafer cleaning unit 108 is positioned between the second-step CMP polishers 802 and 804 and the wafer supply unit 110. Similarly, the second-step CMP polishers 806 and 808 and the wafer cleaning unit 402 are situated between the interface unit and the wafer supply unit on the opposite side of the wafer transfer unit, as compared to the second-step CMP polishers 802 and 804 and the wafer cleaning unit 108. The second-step CMP polishers 806 and 808 are also vertically stacked, next to the interface unit, as shown in FIG. 9. The wafer cleaning unit 402 is positioned between the second-step CMP polishers 806 and 808 and the wafer supply unit. Although the vertically stacked arrangement of the second-step CMP polishers 802, 804, 806 and 808 may be preferred to minimize the footprint of the CMP system, the second-step CMP polishers may instead be horizontally positioned. Thus, in this arrangement, the second-step CMP polisher 804 can be positioned at the same level as the second-step CMP polisher 802 between the wafer cleaning unit 108 and the second-step CMP polisher 802. Similarly, the second-step CMP polisher 808 can be positioned at the same level as the second-step CMP polisher 806 between the wafer cleaning unit 108 and the second-step CMP polisher 806. In an alternative arrangement, the CMP system 800 may include only the second-step CMP polishers 802 and 806.

Similar to the CMP system 600 of FIG. 6, the transferring of semiconductor wafers between the wafer receive station 604 of the interface unit 104, the second-step CMP polishers 802, 804, 806 and 808 and the cleaning units 108 and 402 are performed by the wafer transfer robot 126 of the wafer transfer unit 106. Thus, the wafer transfer robot 126 is configured to transfer a semiconductor wafer from the wafer receive station to any one of the second-step CMP polishers 802, 804, 806 and 808. Furthermore, the wafer transfer robot 126 is configured to transfer a semiconductor wafer from any one of the second-step CMP polishers 802, 804, 806 and 808 to one of the wafer cleaning units 108 and 402. Preferably, the wafer transfer robot 126 is configured to transfer semiconductor wafers from the second-step CMP polishers 802 and 804 to the wafer cleaning unit 108. Similarly, the wafer transfer robot 126 is preferably configured to transfer semiconductor wafers from the second-step CMP polishers 806 and 808 to the wafer cleaning unit 402.

The operation the CMP system 800 of FIG. 8 is now described. Initially, the wafer load cassette 134 with a supply of semiconductor wafers to be processed is inserted into the wafer supply unit 110. The ceiling wafer transfer robot 702 of the wafer transfer unit 106 selects a first semiconductor wafer from the wafer load cassette and transfers that selected wafer from the wafer load cassette to the wafer supply station 602 of the interface unit 104 by moving along the upper track 706 from the wafer supply unit to the interface unit. At the wafer supply station, the thickness of features on the first semiconductor wafer may be measured by the optional thickness measurement unit 119. The semiconductor wafer is picked up from the wafer supply station by one of the wafer transfer robots 120 and 122 of the interface unit 104 and transferred to the wafer load station 114, the wafer load/unload station or one of the wafer carriers of the polishing unit 102. During this transfer from the wafer load cassette to the polishing unit, the semiconductor wafer may be turned over by either the wafer transfer robot 702 of the wafer transfer unit or the wafer transfer robot of the interface unit that transferred the wafer from the wafer supply station 602 to the polishing unit 102.

The semiconductor wafer is then polished by one or more CMP polishers 112 of the polishing unit 102. The polished semiconductor wafer is picked up from the wafer unload station 116, the wafer load/unload station or the wafer carrier of the polishing unit by one of the wafer transfer robots 120 and 122 of the interface unit 104 and transferred to the wafer receive station 604 of the interface unit. The wafer transfer robot that transferred the polished semiconductor wafer to the wafer receive station may be the same wafer transfer robot that transferred the wafer from the wafer supply station 602 to the polishing unit. At the wafer receive station, the thickness of features on the first semiconductor wafer may be measured by an optional thickness measurement unit (not shown). The semiconductor wafer is then picked up from the wafer receive station 604 and transferred to one of the second-step CMP polishers 802 and 804 or one of the second-step CMP polishers 806 and 808 by the wafer transfer robot 126 of the wafer transfer unit 106, depending on whether the wafer is to be processed by the wafer cleaning unit 108 or 402.

If the polished semiconductor wafer is to be processed by the wafer cleaning unit 108, the wafer is transferred from the wafer receive station 604 by the wafer transfer robot 126 of the wafer transfer unit 106 to one of the second-step CMP polishers 802 and 804, where the wafer is further polished. During the transfer of the semiconductor wafer from the polishing unit 102 to one of the second-step CMP polishers 802 and 804, the wafer may be turned over by the wafer transfer robot 126 or the wafer transfer robot of the interface unit 104 that transferred that wafer from the polishing unit to the wafer receive station of the interface unit. The semiconductor wafer is then transferred from the second-step CMP polisher to the wafer cleaning unit 108, where the semiconductor wafer is cleaned, dried and/or measured for feature thickness. The semiconductor wafer is then transferred from the wafer cleaning unit 108 to the wafer unload cassette 136 of the wafer supply unit 110 by the wafer transfer robot 132 of the wafer transfer unit 106.

However, if the polished semiconductor wafer is to be processed by the wafer cleaning unit 402, the wafer is transferred from the wafer receive station 604 by the wafer transfer robot 126 of the wafer transfer unit 106 to one of the second-step CMP polishers 806 and 808, where the wafer is further polished. During the transfer from the polishing unit 102 to one of the second-step CMP polishers 806 and 808, the semiconductor wafer may be turned over by the wafer transfer robot 126 or the wafer transfer robot of the interface unit 104 that transferred that wafer from the polishing unit to the wafer receive station of the interface unit. The semiconductor wafer is then transferred from the second-step CMP polisher to the wafer cleaning unit 402 where the semiconductor wafer is cleaned, dried and/or measured for feature thickness. The semiconductor wafer is then transferred from the wafer cleaning unit 402 to the wafer unload cassette 406 of the wafer supply unit 110 by the wafer transfer robot 404 of the wafer transfer unit 106.

Shortly after the first semiconductor wafer has been transferred from the wafer load cassette 134 of the wafer supply unit 110 to the wafer supply station 602 of the interface unit 104 by the ceiling wafer transfer robot 702 of the wafer transfer unit 106, the wafer transfer robot 702 returns to the wafer supply unit to select and transfer a second semiconductor wafer from the wafer load cassette to the wafer supply station. The second semiconductor wafer is processed in the same manner as the first semiconductor wafer. However, the second semiconductor wafer is polished by one of the second-step CMP polishers 802, 804, 806 and 808 that was not used to polish the first semiconductor wafer. The second semiconductor wafer may be polished by the other second-step CMP polisher that is vertically positioned with respect to the second-step CMP polisher that polished the first semiconductor wafer. Alternatively, the second semiconductor wafer may be polished by one of the second-step CMP polishers that are positioned on the opposite side of the interface unit 104 with respect to the second-step CMP polisher that polished the first semiconductor wafer. Similarly, subsequent semiconductor wafers may be polished by one of the other second-step CMP polishers that was not used to polish the previous semiconductor wafer. In this fashion, all the semiconductor wafers in the wafer load cassette 134 are continually processed by the CMP system 800 such that half of the wafers are polished, cleaned, dried and/or measured for feature thickness by one of the second-step CMP polishers 802 and 804 and the wafer cleaning unit 108, and the other half of the wafers are polished, cleaned, dried and/or measured for feature thickness by one of the second-step CMP polishers 806 and 808 and the wafer cleaning unit 402. The semiconductor wafers that have been processed by one of the second-step CMP polishers 802 and 804 and the wafer cleaning unit 108 are placed in the wafer unload cassette 136 of the wafer supply unit 110, while the semiconductor wafers that have been processed by one of the second-step CMP polishers 806 and 808 and the wafer cleaning unit 402 are placed in the other wafer unload cassette 406.

Similar to the CMP system 600 of FIG. 6, the CMP system 800 of FIG. 8 may be configured to sequentially polish each semiconductor wafer by either the second-step CMP polishers 802 and 804 or the second-step CMP polishers 806 and 808, before being cleaned, dried and/or measured for feature thickness by the wafer cleaning unit 108 or 402. Thus, in this configuration, each semiconductor wafer is either transferred between the second-step CMP polishers 802 and 804 or the second-step CMP polishers 806 and 808 by the wafer transfer robot 126 of the wafer transfer unit 106.

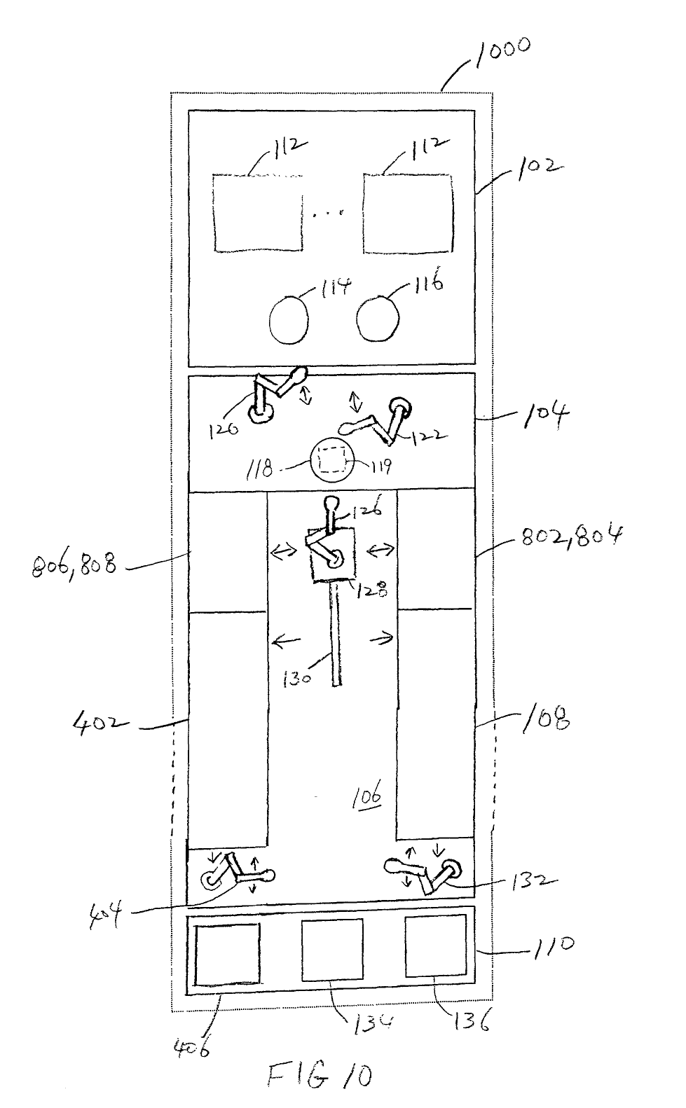

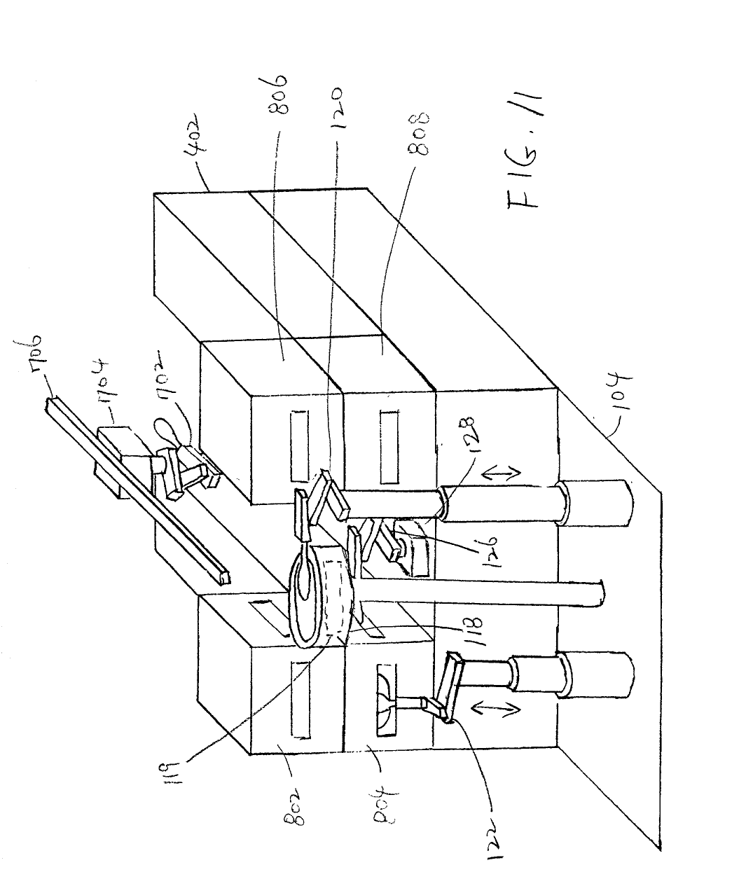

Turning now to FIG. 10, a CMP system 1000 in accordance with a fifth embodiment of the invention is shown. The CMP system 1000 of FIG. 10 is identical to the CMP system 800 of FIG. 8, except that the interface unit 104 of the CMP system 1000 includes the wafer relay station 118, instead of the wafer supply station 602 and the wafer retrieve station 604, as illustrated in FIG. 11. FIG. 11 is a partial perspective view of the CMP system 1000 of FIG. 10 without the wafer supply unit 110 from the viewpoint of the polishing unit 102. In addition, the wafer transfer robots 120 and 122 of the interface unit 104 are configured to directly transfer semiconductor wafers from the polishing unit 102 to one of the second-step CMP polishers 802, 804, 806 and 808, as shown in FIG. 11. The wafer transfer robot 120 is configured to directly transfer semiconductor wafers from the polishing unit 102 to one of the second-step CMP polishers 806 and 808. Similarly, the wafer transfer robot 122 is configured to directly transfer semiconductor wafers from the polishing unit to one of the second-step CMP polishers 802 and 804. Thus, in contrast to the CMP system 800, transfers of polished semiconductor wafers from the polishing unit to one of the second-step CMP polishers 802, 804, 806 and 808 are performed in a single step instead of transferring the polished semiconductor wafers from the polishing unit to the wafer retrieve station 604, and then transferring the wafers to one of the second-step CMP polishers. Consequently, the wafer transfer robot 126 of the wafer transfer unit 106 only transfers semiconductor wafers between the second-step CMP polishers 802, 804, 806 and 808, and between the second-step CMP polishers 802, 804, 806 and 808 and the cleaning units 108 and 402. Other operational aspects of the CMP system 1000 of FIG. 10 are identical to the CMP system 800 of FIG. 8.

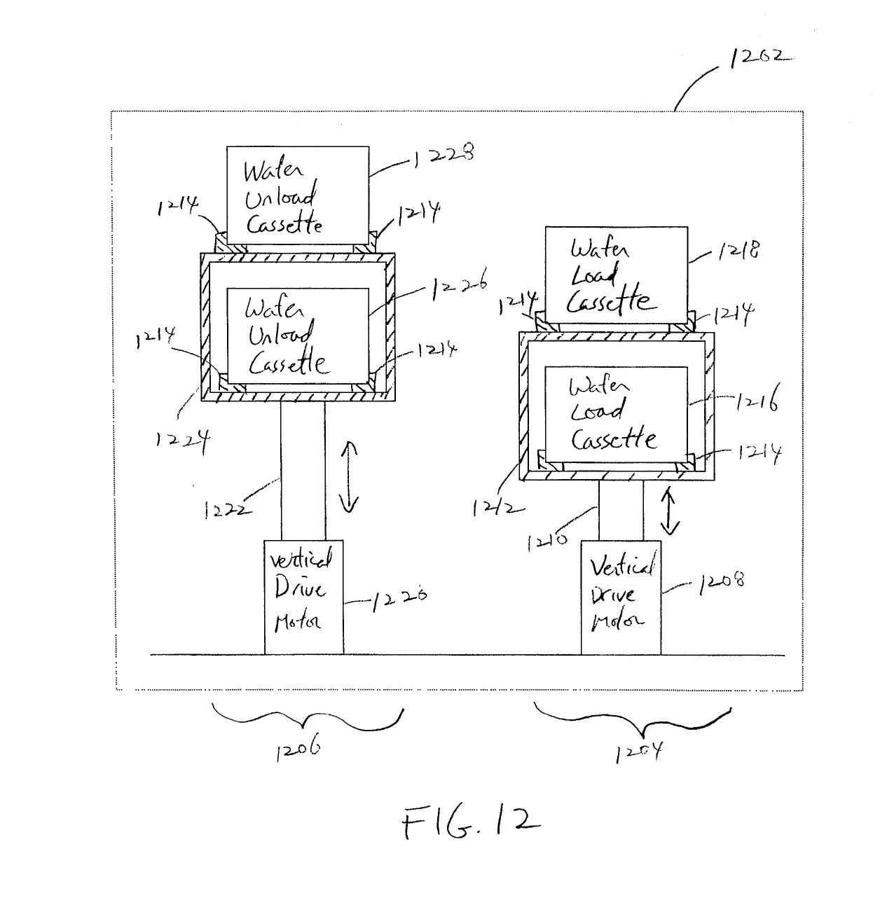

The CMP systems 100, 400, 600, 800 and 1000 of FIGS. 1, 4, 6, 8 and 10 may be modified by replacing the wafer supply unit 110 with an alternative wafer supply unit that can hold additional wafer load and unload cassettes. An alternative wafer supply unit 1202 suitable for the CMP systems 100 and 600 of FIGS. 1 and 6 is shown in FIG. 12. The alternative wafer supply unit 1202 includes a wafer load assembly 1204 and a wafer unload assembly 1206. The wafer load assembly 1204 includes a vertical drive motor 1208, a shaft 1210 and a support frame 1212. Within the support frame 1212 are cassette aligners 1214 that can support a wafer load cassette 1216. Similarly, on top of the support frame are additional cassette aligners 1214 that can support a second wafer load cassette 1218. The vertical drive motor 1208 operates to raise and lower the wafer load cassettes 1216 and 1218 by vertically moving the shaft 1210. Thus, each of the wafer load cassettes can be vertically moved to a particular level.

The wafer load assembly 1204 and the wafer unload assembly 1206 of the alternative wafer supply unit 1202 are identical structures. Thus, the wafer unload assembly 1206 also includes a vertical drive motor 1220, a shaft 1222, a support frame 1224 and cassette aligners 1214, which supports wafer unload cassettes 1226 and 1228. Similar to the wafer load assembly 1204, the vertical drive motor 1220 operates to raise and lower the wafer unload cassettes 1226 and 1228 by vertically moving the shaft 122. Thus, each of the wafer unload cassettes can also be vertically moved to a particular level.

In operation, the wafer load cassette 1218 and the wafer unload cassette 1228 are initially positioned at a predefined level by the vertical drive motors 1208 and 1222 of the wafer load and unload assemblies 1204 and 1206. The semiconductor wafers contained in the wafer load cassette 1218 are sequentially removed, processed and placed in the wafer unload cassette 1228, as described above with respect to the CMP systems 100 and 600 of FIGS. 1 and 6. When all the semiconductor wafers have been removed from the wafer load cassette 1218, the vertical drive motor 1208 of the wafer load assembly 1204 raises the support frame 1212 such that the wafer load cassette 1216 is now at the predefined level. Similarly, when all the semiconductor wafers from the wafer load cassette 1218 have been placed in the wafer unload cassette 1228, the vertical drive motor 1220 of the wafer unload assembly 1206 raises the support frame 1224 such that the wafer unload cassette 1226 is now at the predefined level. The semiconductor wafers contained in the wafer load cassette 1216 can then be sequentially removed, processed and placed in the wafer unload cassette 1226. Alternatively, the wafer load and unload cassettes 1216 and 1226 can be initially positioned at the predefined level and the wafer load and unload cassettes 1218 and 1228 can be lowered to the predefined level when all the semiconductor wafers from the wafer load cassette 1216 have been processed and placed in the wafer unload cassette 1226. In this fashion, more semiconductor wafers can be continually processed by the CMP systems 100 and 600 of FIGS. 1 and 6 without having to manually replace used wafer load and unload cassettes.

In an alternative configuration, one or both of the wafer load and unload assemblies 1204 and 1206 are designed to be stationary. That is, the wafer load and unload assemblies may be designed to hold the load and wafer cassettes 1216, 1218,1226 and 1228 at fixed levels. Thus, in this configuration, one or both of the wafer load and unload assemblies do not include the vertical drive motors 1208 and/or 1220 that raise and lower the wafer cassettes. Instead, the wafer transfer 90 robot 126 of the wafer transfer unit 106 (not shown in FIG. 12) vertically moves to remove semiconductor wafers from both of the wafer load cassettes 1216 and 1218, if the wafer load assembly 1204 is stationary. Similarly, the wafer transfer robot 132 of the wafer transfer unit 106 (not shown in FIG. 12) vertically moves to insert semiconductor wafers into both of the wafer unload cassettes 1226 and 1228, if the wafer unload assembly 1206 is stationary.

Although the wafer load and unload assemblies 1204 and 1206 have been described and illustrated as being configured to vertically hold two wafer cassettes, these assemblies can be designed to vertically hold additional wafer cassettes. For example, an additional support frame may be attached above each of the support frames 1212 and 1224 of the wafer load and unload assemblies to hold a third load cassette and a third unload cassette. Thus, in this example, semiconductor wafers from three unload cassettes can be continuously processed without having to change wafer load and unload cassettes.

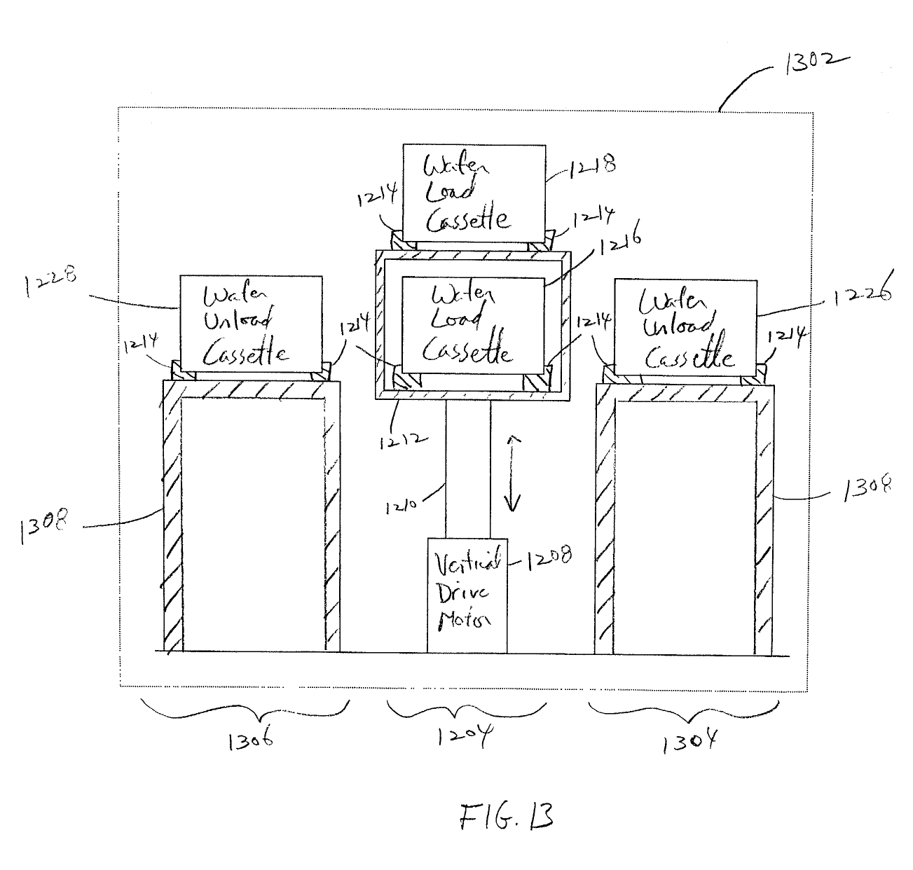

An alternative wafer supply unit 1302 suitable for the CMP systems 400, 800 and 1000 of FIGS. 4, 8 and 10 is shown in FIG. 13. Similar to the alternative wafer supply unit 1202 of FIG. 12, the alternative wafer supply unit 1302 includes the wafer load assembly 1204. However, the alternative wafer supply unit 1302 includes stationary wafer unload assemblies 1304 and 1306. The stationary wafer unload assemblies are positioned such that the wafer load assembly 1204 is situated between the stationary wafer unload assemblies. Each of the stationary wafer unload assemblies includes a support structure 1308 and cassette aligners 1214 to hold a single wafer unload cassette, e.g., the wafer unload cassettes 1226 and 1228.

In operation, the wafer load cassette 1218 is initially positioned by the vertical drive motor 1208 of the wafer load assembly 1204 at a level where the wafer unload cassette 1226 and 1228 are situated. The semiconductor wafers contained in the wafer load cassette 1218 are sequentially removed, processed and placed in the wafer unload cassettes 1226 and 1228, as described above with respect to the CMP systems 400, 800 and 1000 of FIGS. 4, 8 and 10. When all the semiconductor wafers have been removed from the wafer load cassette 1218, the vertical drive motor 1208 of the wafer load assembly 1204 raises the support frame 1214 such that the wafer load cassette 1216 is level with the wafer unload cassettes 1226 and 1228, as illustrated in FIG. 13. The semiconductor wafers contained in the wafer load cassette are then sequentially processed. Alternatively, the wafer load cassette 1216 can be initially positioned at the level of the wafer unload cassettes 1226 and 1228 and the wafer load cassette 1218 can be lowered to that level when all the semiconductor wafers from the wafer load cassette 1216 have been processed and placed in the wafer unload cassettes 1226 and 1228. In this fashion, more semiconductor wafers can be continually processed by the CMP systems 400, 800 and 1000 of FIGS. 4, 8 and 10 without having to manually replace the used wafer load cassette with another wafer load cassette with additional semiconductor wafers to be processed.

Similar to the alternative wafer supply unit 1202 of FIG. 12, the wafer load assembly 1204 of the alternative wafer supply unit 1302 of FIG. 13 may be configured to be stationary. Thus, in this configuration, the wafer transfer robot 126 or 702 of the wafer transfer unit 106 (not shown in FIG. 13) vertically moves to selectively remove semiconductor wafers from one of the wafer load cassettes 1216 and 1218 without raising and lowering the wafer load cassettes. In addition, one or both of the wafer unload assemblies 1304 and 1306 may be configured to vertically move the wafer unload cassettes 1226 and/or 1228. Thus, the wafer unload assemblies may be structurally similar to the wafer unload assembly 1206 of the alternative wafer supply unit 1202 of FIG. 12. Furthermore, the wafer load and unload assemblies 1204,1304 and 1306 of the alternative wafer supply unit 1302 may be configured to vertically hold additional wafer cassettes.

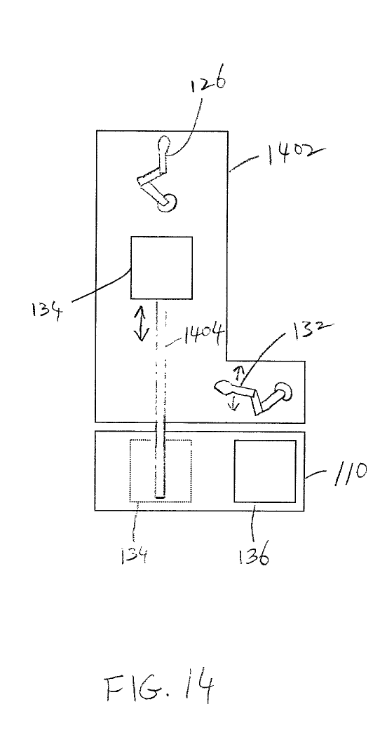

The CMP systems 100, 400, 600, 800 and 1000 of FIGS. 1, 4, 6, 8 and 10 may also be modified by replacing the wafer transfer unit 106 with an alternative wafer transfer unit. In FIG. 14, a first alternative wafer transfer unit 1402 suitable for the CMP system 100 of FIG. 1 is shown. Similar to the wafer transfer unit 106 of the CMP system 100, the alternative wafer transfer unit 1402 also includes the wafer transfer robots 126 and 132. However, the wafer transfer robot 126 is stationary. That is, the wafer transfer robot 126 does not move along a track, such as the track 130 shown in FIG. 1. Instead, the alternative wafer transfer unit 1402 is configured such that the wafer load cassette 134 of the wafer supply unit 110 moves toward the wafer transfer robot 126 from the wafer supply unit to supply semiconductor wafers. Thus, the alternative wafer transfer unit 1402 includes a track 1404 that extends from the wafer supply unit to the wafer transfer robot 126, which allows the wafer load cassette 134 to move from the wafer supply unit toward the wafer transfer robot 126 when the wafer load cassette is inserted into the wafer supply unit. The track 1404 also allows the wafer load cassette 134 to return to the wafer supply unit when all the semiconductor wafers in the wafer load cassette have been processed. Since the wafer load cassette 134 is brought to the wafer transfer robot 126 from the wafer supply unit 110, the wafer transfer robot 126 does not have to repeatedly travel between the wafer supply unit and the interface unit 104 (not shown in FIG. 14) to transfer semiconductor wafers from the wafer load cassette 134 to the interface unit.

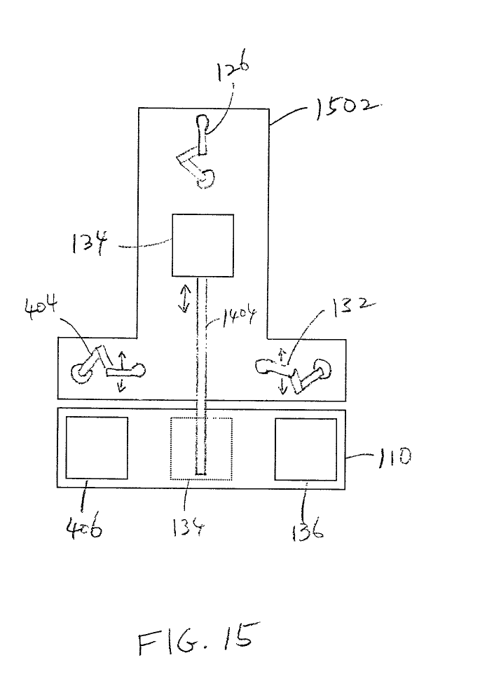

Turning to FIG. 15, a first alternative wafer transfer unit 1502 suitable for the CMP systems 400, 800 and 1000 of FIGS. 4, 8 and 10 is shown. Similar to the alternative wafer transfer unit 1402 of FIG. 14, the alternative wafer transfer 1502 unit includes the track 1404 that extends from the wafer supply unit 110 to the stationary wafer transfer robot 126. Thus, the wafer load cassette 134 can move between the wafer supply unit 110 and the wafer transfer robot 126. Furthermore, similar to the wafer transfer unit 106 of the CMP systems 400, 800 and 1000, the alternative wafer transfer unit 1502 includes the wafer transfer robots 132 and 404 to transfer semiconductor wafers from the cleaning units 108 and 402 (not shown in FIG. 14) to the wafer unload cassettes 136 and 406 of the wafer supply unit 110.

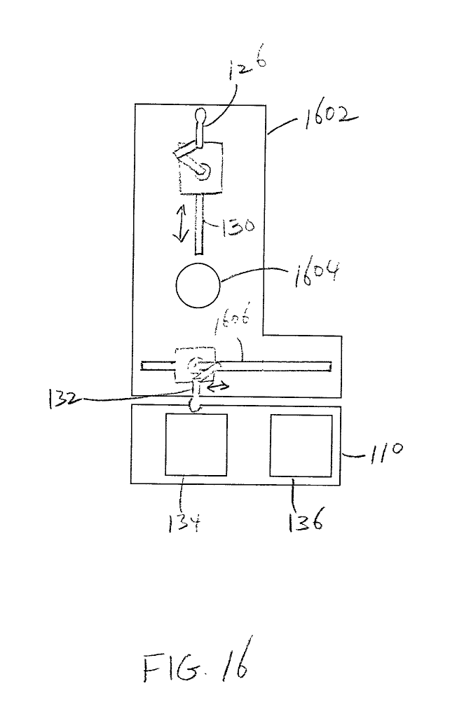

In FIG. 16, a second alternative wafer transfer unit 1602 suitable for the CMP systems 100 and 600 of FIGS. 1 and 6 is shown. Similar to the wafer transfer unit 106, the alternative wafer transfer unit 1602 also includes the wafer transfer robots 126 and 132. However, the alternative wafer transfer unit 1602 further includes a wafer relay station 1604. In addition, the alternative wafer transfer unit 1602 includes a second track 1606, which is used by the wafer transfer robot 132. The track 1606 is substantially perpendicular to the track 130 for the wafer transfer robot 126 and runs along a direction defined by the wafer load and unload cassettes 134 and 136 of the wafer supply unit 110. Thus, the wafer transfer robot 132 can move between the wafer load cassette 134 and the wafer unload cassette 136 to remove semiconductor wafers from the wafer load cassette and to insert the wafers into the wafer unload cassette. The wafer relay station 1604 is positioned between the tracks 130 and 1606. The wafer relay station 1604 allows semiconductor wafers to be transferred from the wafer transfer robot 132 to the wafer transfer robot 126.

In operation, the wafer transfer robot 132 of the alternative wafer transfer unit 1602 is positioned in front of the wafer load cassette 134. The wafer transfer robot 132 transfers a semiconductor wafer to be processed from the wafer load cassette 134 of the wafer supply unit 110 to the wafer relay station 1604. The semiconductor wafer is then picked up by the wafer transfer robot 126 and transferred to the interface unit 104 (not shown in FIG. 16). After the semiconductor wafer has been polished, the wafer is transferred from the interface unit to one of the second-step CMP polishers 606 and 608 or the cleaning unit 108 (not shown in FIG. 16) by the wafer transfer robot 126, depending on the CMP system. In the CMP system 100 of FIG. 1, the semiconductor wafer is directly transferred from the interface unit to the cleaning unit 108 by the wafer transfer robot 126. In the CMP system 600 of FIG. 6, the semiconductor wafer is initially transferred from the interface unit to the second-step CMP polishers 606 and 608 to further polish the wafer, prior to being transferred to the cleaning unit 108. After the semiconductor wafer has been processed by the cleaning unit 108, the wafer is transferred from the cleaning unit to the wafer unload cassette 136 of the wafer supply unit 110 by the wafer transfer robot 132. Thus, the wafer transfer robot 132 moves back and forth between the wafer load and unload cassettes 134 and 136 to remove semiconductor wafers from the wafer load cassette and to insert processed semiconductor wafers into the wafer unload cassette. Consequently, the transferring of semiconductor wafers from the wafer load cassette of the wafer supply unit to the interface unit is performed in two stages, which are each performed by one of the wafer transfer robots 132 and 126. Thus, the wafer transfer robot 126 does not have to repeatedly travel between the wafer supply unit 110 and the interface unit 104 to transfer semiconductor wafers from the wafer unload cassette of the wafer supply unit to the interface unit.

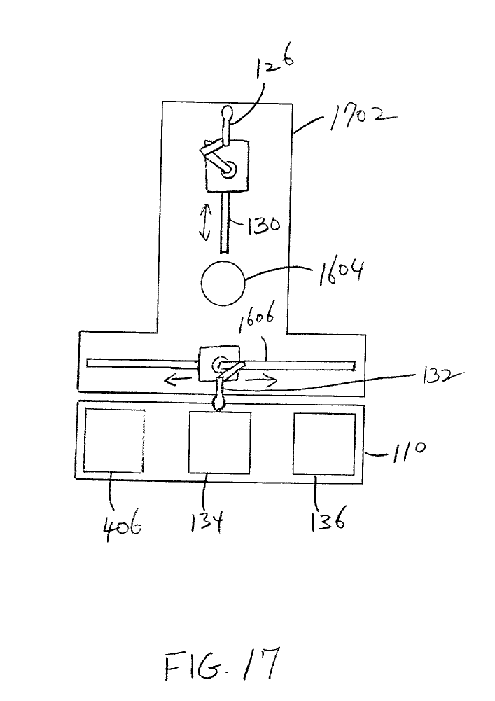

Turning to FIG. 17, a second alternative wafer transfer unit 1702 suitable for the CMP systems 400, 800 and 1000 of FIGS. 4, 8 and 10 is shown. The alternative wafer transfer unit 1702 is virtually identical to the alternative wafer transfer unit 1602 of FIG. 16. The only difference is that the track 1606 is extended so that the wafer transfer robot 132 can reach the wafer unload cassette 406 of the wafer supply unit 110. In this alternative wafer transfer unit 1702, the wafer transfer robot 132 transfers processed semiconductor wafers from the wafer cleaning unit 404 (not shown in FIG. 17) to the wafer unload cassette 406, in addition to transferring semiconductor wafers from the wafer load cassette 134 to the wafer relay station 1604 and transferring processed semiconductor wafers from the wafer cleaning unit 108 (not shown in FIG. 17) to the wafer unload cassette 136. In contrast to the wafer transfer unit 106 of the CMP systems 800 and 1000, since the wafer transfer robots 126 and 132 transfer semiconductor wafers from the wafer load cassette 134 of the wafer supply unit 110 to the interface unit 104 (not shown in FIG. 17), the ceiling wafer transfer robot 702 is not needed in this alternative wafer transfer unit 1702.

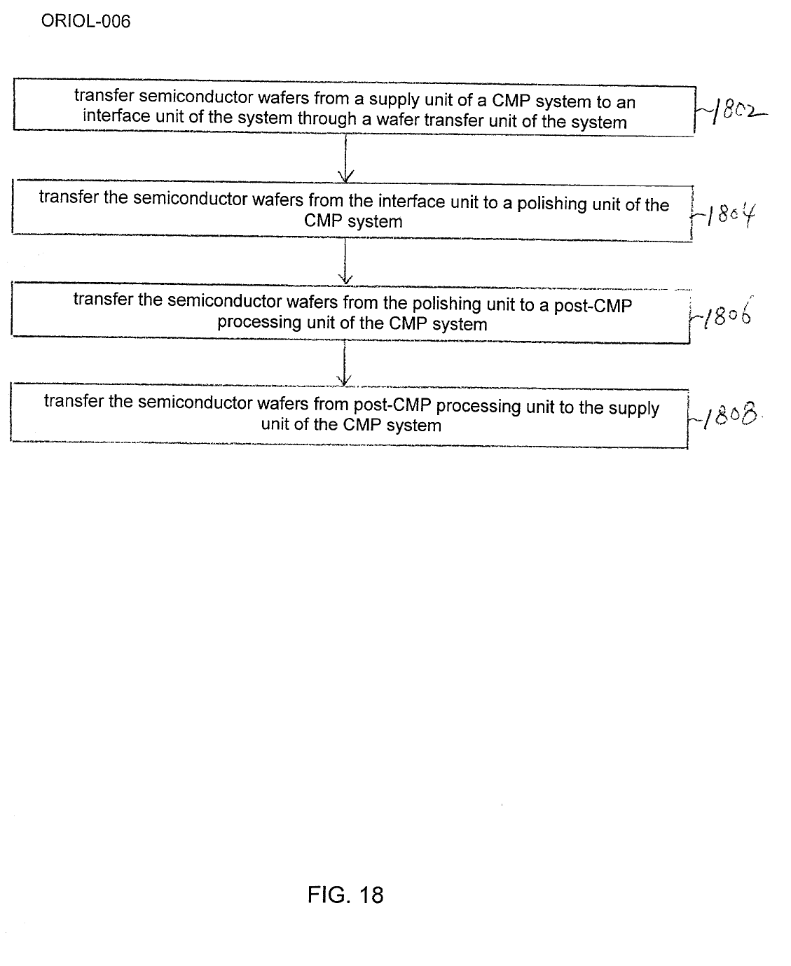

A method of processing semiconductor wafers in accordance with the invention is described with reference to a flow diagram of FIG. 18. At step 1802, semiconductor wafers are transferred from a supply unit of a CMP system to an interface unit of the system through a wafer transfer unit of the system, where the wafer transfer unit is located between the supply unit and the interface unit. The interface unit and the wafer transfer unit can be considered as regions of the CMP system. Next, at step 1804, the semiconductor wafers are transferred from the interface unit to a polishing unit of the CMP system. In an embodiment, the semiconductor wafers are transferred from the interface unit to the polishing unit using a pair of wafer transfer robots such that some of the wafers are transferred to the polishing unit by one of the wafer transfer robots and some of the wafer are transferred to the polishing unit by the other wafer transfer robot. At step 1806, the semiconductor wafers are transferred from the polishing unit to a post-CMP processing unit. The post-CMP processing unit may include one or more wafer cleaners and one or more second-step CMP polishers. Next, at step 1808, the semiconductor wafers are transferred from the post-CMP processing unit to the supply unit of the CMP system.

The foregoing descriptions of specific embodiments of the invention have been presented for purposes of illustration and description. They are not intended to be exhaustive or to limit the invention to the precise embodiments disclosed, and naturally many modifications and variations are possible in light of the above teaching. The embodiments were chosen and described in order to explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A system for polishing surfaces of objects comprising:
a polishing unit that is configured to polish said objects; and
a pair of interface mechanisms that are each configured to transfer some of said objects to said polishing unit and to transfer some of said objects that have been polished from said polishing unit, said pair of interface mechanisms cooperatively transferring said object to and from said polishing unit to efficiently process said objects through said polishing unit.

2. The system of claim 1 further comprising a post-polishing unit that is configured to process said objects after said objects have been polished by said polishing unit, said post-polishing unit being positioned such that at least one of said pair of interface mechanisms can transfer some of said objects from said polishing unit to said post-polishing unit.

3. The system of claim 2 further comprising:
a supply unit that provides said objects, said supply unit being positioned such that said post-polishing unit is positioned between said polishing unit and said supply unit; and
a supply mechanism that is configured to transfer said objects from said supply unit to said pair of interface mechanisms.

4. The system of claim 3 wherein said supply unit includes an object load assembly and an object unload assembly, each of said object load assembly and said object unload assembly being configured to vertically position a plurality of object storage housings.

5. The system of claim 4 wherein one of said object load assembly and said object unload assembly is configured to vertically move said plurality of object storage housings.

6. The system of claim 3 wherein said supply mechanism is configured to be mobile to travel between said supply unit and said interface mechanisms to transfer said objects from said supply unit to said interface mechanisms.

7. The system of claim 3 wherein said supply unit includes an object storage housing that is configured to be mobile to travel from said supply unit to said supply mechanism.

8. The system of claim 3 wherein said post-polishing unit includes a first object cleaner that is configured to clean some of said objects that have been polished by said polishing unit.

9. The system of claim 8 wherein said first object cleaner includes a thickness measurement unit to measure the thickness of features on said surfaces of said objects.

10. The system of claim 8 further comprising a dual-functioning object transfer mechanism that is positioned to transfer said objects from said supply unit to said supply mechanism and to transfer some of said objects from said first object cleaner to said supply unit.

11. The system of claim 10 wherein said dual-functioning object transfer mechanism is configured to be mobile to have access to different sections of said supply unit.

12. The system of claim 8 wherein said post-polishing unit further includes a second object cleaner that is configured to clean some of said objects that have been polished by said polishing unit, said first object cleaner being positioned on one side of said supply mechanism between said polishing unit and said supply unit, said second object cleaner being positioned on an opposite side of said supply mechanism between said polishing unit and said supply unit.

13. The system of claim 12 wherein said post-polishing unit includes first and second secondary polishers to further polish some of said objects that have been polished by said polishing unit, said first secondary polisher being positioned on the same side of said supply mechanism as said first object cleaner, said second secondary polisher being positioned on the same side of said supply mechanism as said second object cleaner.

14. The system of claim 13 wherein said post-polishing unit includes third and fourth secondary polishers to further polish some of said objects that have been polished by said polishing unit, said third secondary polisher being positioned on the same side of said supply mechanism as said first object cleaner, said fourth secondary polisher being positioned on the same side of said supply mechanism as said second object cleaner.

15. The system of claim 14 wherein said first and third secondary polishers are vertically positioned such that said first secondary polisher is situated below said third secondary polisher, and wherein said second and fourth secondary polishers are vertically positioned such that said second secondary polisher is situated below said fourth secondary polisher.

16. The system of claim 8 wherein said post-polishing unit includes a first secondary polisher to further polish some of said objects that have been polished by said polishing unit, said first secondary polisher being positioned on one side of said supply mechanism between said polishing unit and said supply unit, said first object cleaner being positioned on an opposite side of said supply mechanism between said polishing unit and said supply unit.

17. The system of claim 3 wherein said supply unit includes an object load assembly that is configured to vertically position a plurality of object storage housings.

18. The system of claim 17 wherein said object load assembly is configured to vertically move said plurality of object storage housings.

19. The system of claim 17 wherein said supply unit further includes object unload assemblies that are each configured to vertically position a plurality of object storage housings.

20. The system of claim 19 wherein at least one of said object unload assemblies is configured to vertically move said plurality of object storage housings that are positioned by that object unload assembly.

21. The system of claim 1 further comprising a first object transfer station to receive said objects that are to be transferred to said polishing unit by one of said pair of interface mechanisms.

22. The system of claim 21 wherein said first object transfer station includes a thickness measurement unit to measure the thickness of features on said surfaces of said objects.

23. The system of claim 21 further comprising a second object transfer station to receive said objects that have been polished by said polishing unit, said second object transfer station being vertically positioned with respect to said first object transfer station.

24. A system for polishing surfaces of objects comprising:
a supply unit that is configured to accommodate a plurality of said objects;
a polishing unit that is configured to polish said objects;
a post-polishing unit that is configured to process said objects after being polished by said polishing unit;
an intermediate object transfer mechanism that is configured to transfer said objects between said polishing unit and said post-polishing unit; and
a supplying mechanism that is configured to transfer said objects from said supply unit to said intermediate object transfer mechanism such that said objects can be relayed to said polishing unit.

25. The system of claim 24 wherein said intermediate object transfer mechanism includes a first object transfer device and a second object transfer device that are configured to selectively transfer objects to and from said polishing unit.

26. The system of claim 25 wherein one of said first and second object transfer devices is configured to directly transfer some of said objects from said polishing unit to said post-polishing unit.

27. The system of claim 24 wherein said supply unit includes an object load assembly and an object unload assembly, each of said object load assembly and said object unload assembly being configured to vertically position a plurality of object storage housings.

28. The system of claim 27 wherein one of said object load assembly and said object unload assembly is configured to vertically move said plurality of object storage housings.

29. The system of claim 24 wherein said supply mechanism is configured to be mobile to travel between said supply unit and said intermediate object transfer mechanism to transfer said objects from said supply unit to said intermediate object transfer mechanism.

30. The system of claim 24 wherein said supply unit includes an object storage housing that is configured to be mobile to travel from said supply unit to said supply mechanism.

31. The system of claim 24 further comprising a dual-functioning object transfer mechanism that is positioned to transfer said objects from said supply unit to said supply mechanism and to transfer some of said objects from said post-polishing unit to said supply unit.

32. The system of claim 31 wherein said dual-functioning object transfer mechanism is configured to be mobile to have access to different sections of said supply unit.

33. The system of claim 24 wherein said post-polishing unit includes a first object cleaner that is configured to clean some of said objects that have been polished by said polishing unit.

34. The system of claim 33 wherein said first object cleaner includes a thickness measurement unit to measure the thickness of features on said surfaces of said objects.

35. The system of claim 33 wherein said post-polishing unit includes a secondary polisher to further polish some of said objects that have been polished by said polishing unit, said secondary polisher being positioned on one side of said supply mechanism between said polishing unit and said supply unit, said first object cleaner being positioned on an opposite side of said supply mechanism between said polishing unit and said supply unit.

36. The system of claim 33 wherein said post-polishing unit further includes a second object cleaner that is configured to clean some of said objects that have been polished by said polishing unit, said first object cleaner being positioned on one side of said supply mechanism between said polishing unit and said supply unit, said second object cleaner being positioned on an opposite side of said supply mechanism between said polishing unit and said supply unit.

37. The system of claim 36 wherein said post-polishing unit includes first and second secondary polishers to further polish some of said objects that have been polished by said polishing unit, said first secondary polisher being positioned on the same side of said supply mechanism as said first object cleaner, said second secondary polisher being positioned on the same side of said supply mechanism as said second object cleaner.

38. The system of claim 37 wherein said post-polishing unit includes third and fourth secondary polishers to further polish some of said objects that have been polished by said polishing unit, said third secondary polisher being positioned on the same side of said supply mechanism as said first object cleaner, said fourth secondary polisher being positioned on the same side of said supply mechanism as said second object cleaner.

39. The system of claim 38 wherein said first and third secondary polishers are vertically positioned such that said first secondary polisher is situated below said third secondary polisher, and wherein said second and fourth secondary polishers are vertically positioned such that said second secondary polisher is situated below said fourth secondary polisher.

40. The system of claim 24 wherein said supply unit includes an object load assembly that is configured to vertically position a plurality of object storage housings.

41. The system of claim 40 wherein said object load assembly is configured to vertically move said plurality of object storage housings.

42. The system of claim 41 wherein said supply unit further includes object unload assemblies that are each configured to vertically position a plurality of object storage housings.

43. The system of claim 42 wherein at least one of said object unload assemblies is configured to vertically move said plurality of object storage housings that are positioned by that object unload assembly.

44. The system of claim 24 further comprising a first object transfer station to receive said objects that are to be transferred to said polishing unit by said intermediate object transfer mechanism.

45. The system of claim 44 wherein said first object transfer station includes a thickness measurement unit to measure the thickness of features on said surfaces of said objects.

46. The system of claim 44 further comprising a second object transfer station to receive said objects that have been polished by said polishing unit, said second object transfer station being vertically positioned with respect to said first object transfer station.

47. A method of processing objects to be polished comprising:
selectively transferring said objects to a polishing unit of a polishing system using first and second object transfer mechanisms such that some of said objects are transferred to said polishing unit by said first object transfer mechanism and some of said objects are transferred to said polishing unit by said second object transfer mechanism; and
selectively transferring said objects that have been polished from said polishing unit of said polishing system using said first and second object transfer mechanisms such that some of said objects are transferred from said polishing unit by said first object transfer mechanism and some of said objects are transferred from said polishing unit by said second object transfer mechanism.

48. The method of claim 47 further comprising:
transferring said objects from a supply unit of said polishing system to an interface region of said polishing system through an object transfer region of said polishing system, said interface region including said first and second object transfer mechanisms; and
transferring said objects that have been polished from said polishing unit to a post-polishing unit of said polishing system.

49. The method of claim 48 further comprising measuring the thickness of features on surfaces of said objects at a measurement station of an object cleaner of said post-polishing unit.

50. The method of claim 48 wherein said step of transferring said objects that have been polished from said polishing unit to said post-polishing unit includes:
transferring some of said objects to an object cleaner of said post-polishing unit to clean said objects; and
transferring some of said objects to a secondary polisher of said post-polishing unit to further polish said objects, said object cleaner being positioned on one side of said object transfer region between said polishing unit and said supply unit, said secondary polisher being positioned on an opposite side of said object transfer region between said polishing unit and said supply unit.

51. The method of claim 48 wherein said step of transferring said objects that have been polished from said polishing unit to said post-polishing unit includes:
transferring some of said objects to a first object cleaner of said post-polishing unit to clean said objects; and
transferring some of said objects to a second object cleaner of said post-polishing unit, said first object cleaner being positioned on one side of said object transfer region between said polishing unit and said supply unit, said second object cleaner being positioned on an opposite side of said object transfer region between said polishing unit and said supply unit.

52. The method of claim 51 wherein said step of transferring said objects that have been polished from said polishing unit to said post-polishing unit includes selectively transferring some of said objects to first and second secondary polishers of said post-polishing unit to further polish said objects, said first secondary polisher being positioned on the same side of said object transfer region as said first object cleaner, said second secondary polisher being positioned on the same side of said object transfer region as said second object cleaner.

53. The method of 48 further comprising a step of laterally moving an object storage housing from said supply unit across a portion of said object transfer region of said polishing unit to position said object storage housing closer to said interface region of said polishing system.

54. The method of 47 further comprising a step of vertically moving a plurality of object storage housings within said supply unit of said polishing system.

55. The method of claim 47 wherein said step of transferring said objects from said supply unit of said polishing system to said interface region of said polishing system through said object transfer region of said polishing system includes serially relaying said objects to third and fourth object transfer mechanisms to transfer said objects from said supply unit to said interface region, said third and fourth object transfer mechanisms being positioned in said object transfer region of said polishing system.

56. The method of claim 55 further comprising a step of transferring some of said objects from said post-polishing unit to said supply unit using said third object transfer mechanism.

57. A method of processing objects to be polished comprising:
transferring said objects from a supply unit of a polishing system to an interface region of said polishing system through an object transfer region of said polishing system, said object transfer region being located between said supply unit and said interface region;
transferring said objects from said interface region to a polishing unit of said polishing system; and
transferring said objects from said polishing unit to a post-polishing unit of said polishing system.

58. The method of claim 57 wherein said step of transferring said objects from said interface region to said polishing unit of said polishing system includes selectively transferring said objects to said polishing unit using first and second object transfer mechanisms such that some of said objects are transferred by said first object transfer mechanism and some of said objects are transferred by said second object transfer mechanism.

59. The method of claim 57 further comprising measuring the thickness of features on surfaces of said objects at a measurement station of an object cleaner of said post-polishing unit.

60. The method of claim 57 wherein said step of transferring said objects from said polishing unit to said post-polishing unit includes:
transferring some of said objects to an object cleaner of said post-polishing unit to clean said objects; and
transferring some of said objects to a secondary polisher of said post-polishing unit to further polish said objects, said object cleaner being positioned on one side of said object transfer region between said polishing unit and said supply unit, said secondary polisher being positioned on an opposite side of said object transfer region between said polishing unit and said supply unit.

61. The method of claim 57 wherein said step of transferring said objects from said polishing unit to said post-polishing unit includes:
transferring some of said objects to a first object cleaner of said post-polishing unit to clean said objects; and
transferring some of said objects to a second object cleaner of said post-polishing unit, said first object cleaner being positioned on one side of said object transfer region between said polishing unit and said supply unit, said second object cleaner being positioned on an opposite side of said object transfer region between said polishing unit and said supply unit.

62. The method of claim 61 wherein said step of transferring said objects from said polishing unit to said post-polishing unit includes selectively transferring some of said objects to first and second secondary polishers of said post-polishing unit to further polish said objects, said first secondary polisher being positioned on the same side of said object transfer region as said first object cleaner, said second secondary polisher being positioned on the same side of said object transfer region as said second object cleaner.

63. The method of 58 further comprising a step of vertically moving a plurality of object storage housings within said supply unit of said polishing system.

64. The method of claim 57 wherein said step of transferring said objects from said supply unit of said polishing system to said interface region of said polishing system through said object transfer region of said polishing system includes serially relaying said objects to first and second object transfer mechanisms to transfer said objects from said supply unit to said interface region, said first and second object transfer mechanisms being positioned in said object transfer region of said polishing system.

65. The method of claim 64 further comprising a step of transferring some of said objects from said post-polishing unit to said supply unit using said first object transfer mechanism.

66. The method of 57 further comprising a step of laterally moving an object storage housing from said supply unit across a portion of said object transfer region of said polishing system to position said object storage housing close to said interface region of said polishing system.
